(19) United States
(12) Patent Application Publication
(10) Pub. No.: US 2009/0224818 A1
(43) Pub. Date: Sep. 10, 2009

(54) SEMICONDUCTOR DEVICE FOR CONTROLLING SUPPLY OF DRIVING SIGNALS

(75) Inventors: Tsuyoshi Yoneyama, Chino-shi (JP); Atsushi Yamada, Nagoya-shi (JP)

Correspondence Address: OLIFF & BERRIDGE, PLC, P.O. BOX 320850, ALEXANDRIA, VA, 22320-4850, US

(73) Assignee: Seiko Epson Corporation, Tokyo (JP)

(21) Appl. No.: 12/400,182

(22) Filed: Mar. 9, 2009

(30) Foreign Application Priority Data
Mar. 7, 2008 (JP) 2008-057240
Nov. 11, 2008 (JP) 2008-288888

(51) Int. Cl. H03L 5/02

(52) U.S. Cl. 327/333

(57) ABSTRACT

A driving signal supply control semiconductor device includes a load driving device that includes: (i) a bridge circuit including a high-side first transistor and a low-side second transistor, the transistors being electrically connected to a load as an object to be driven and being turned on or off to energize or de-energize the load; (ii) a first driving circuit driving the first transistor; (iii) a second driving circuit driving the second transistor; (iv) a first power supply circuit supplying driving power to the first driving circuit; (v) a second power supply circuit supplying driving power to the second driving circuit; (vi) a supply content setting unit setting a supply content of each of driving signals regarding low-power driving of the load driving device, according to a standby status of the load; and (vii) a driving signal supply control unit controlling supply of the driving signals to the first and the second power supply circuits. Based on the supply content set by the supply content setting unit, the driving signal supply control unit controls independently contents of the driving signals supplied to each of the first and the second power supply circuits such that the load driving device is driven with lower power consumption than in a normal driving status of the load driving device.

### BACKGROUND

1. Technical Field

The present invention relates to a driving signal supply control

semiconductor device suitable to reduce the amount of power consumption of a constant voltage power supply circuit used when driving a driving device that includes a bridge circuit driving a load such as a motor.

2. Related Art

Conventionally, as circuits driving a load such as a motor, there are

known as a half-bridge circuit, a full-bridge circuit, and the like. Those circuits include a high-potential-side (high-side) transistor and a low-potential-side (low-side) transistor. The high-side and the low-side transistors are independently controlled to be driven so as to be turned on or off, thereby energizing or de-energizing the load.

Additionally, a load requiring a relatively high power for high-speed switching operation uses metal-oxide-semiconductor field-effect transistors (MOSFETs) designed for high-current applications, as transistors included in a bridge circuit. A double-diffused MOSFET (DMOS) is an example of the high-current MOSFETs.

For example, when the high-side and the low-side transistors included in the bridge circuit are both N-channel DMOSFETs, a charge pump DC/DC converter may be used as a power supply circuit that supplies power for driving the high-side transistors to pre-drivers. Meanwhile, for example, a linear regulator such as a low drop out (LDO) regulator may be used as a power supply circuit supplying power for driving the low-side transistors to the pre-drivers. In particular, in a linear regulator using an operational amplifier to control an on resistance of output transistors connected between input and output terminals so as to maintain a constant output voltage, the output transistors are not be pulse-driven but are continuously driven. Since power consumption of a driving circuit section increases upon operation, power loss in the output transistors also increases. Additionally, in general, the power supply circuit needs to continuously supply a bias voltage for outputting a clock signal or bias current even in a standby status of the load.

An example of a technology reducing the power consumption of a driving device controlling driving of a motor is a motor control device disclosed in JP-A-2001-86790.

The disclosed motor control device includes motor drivers including an H-bridge circuit, pre-drivers driving the motor drivers, a constant voltage circuit, and a power supply control circuit controlling power supply to the pre-drivers. When no supply control is required, such as when the motor is in a stopped state (e.g. in a standby status of the motor), the power supply control circuit stops supplying power to the pre-drivers. Thereby, in the standby status of the motor, operation of the pre-drivers can be stopped to stop the motor drivers, thus reducing the amount of electric current consumed in the standby status.

However, in the conventional motor control device as above, in the standby status of the motor, power supply to all of the pre-divers driving both the high-side and the low-side transistors is stopped. Thus, when the motors status is shifted from power off to power on, power needs to be supplied again to all the pre-drivers in the power-off status to allow the pre-drivers to return to a normal operation status. Returning to normal operation takes time, thereby delaying response time until the load can be driven upon restarting.

Additionally, even if the pre-drivers stop driving the load, the power supply circuit continues to operate. Thus, the amount of power consumption in the power supply circuit cannot be reduced.

### SUMMARY

Accordingly, the present invention has been accomplished focusing on solutions to the unsolved problems in the conventional technology. An advantage of the invention is to provide a semiconductor device suitable to control driving of a power supply circuit and the like at an appropriate power level according to purposes and statuses of the device.

In order to provide the advantage, according to a first aspect of the invention, there is provided a driving signal supply control semiconductor device. The driving signal supply control semiconductor device of the first aspect includes a load driving device that includes (i) a bridge circuit including a high-side first transistor and a low-side second transistor, the transistors being electrically connected to a load as an object to be driven and being turned on or off to energize or de-energize the load; (ii) a first driving circuit driving the first transistor; (iii) a second driving circuit driving the second transistor; (iv) a first power supply circuit supplying driving power to the first driving circuit; (v) a second power supply circuit supplying driving power to the second driving circuit; (vi) a supply content setting unit setting a supply content of each of driving signals regarding low-power driving of the load driving device, according to a standby status of the load; and (vii) a driving signal supply control unit controlling supply of the driving signals to the first and the second power supply circuits, the driving signal supply control unit controlling independently contents of the driving signals supplied to each of the first and the second power supply circuits such that the load driving device is driven with lower power consumption than in a normal driving status of the load driving device, based on the supply content set by the supply content setting unit.

In the semiconductor device of the first aspect, according to the

standby status of the load, the supply content setting unit sets a predetermined supply content. Then, based on the set supply content, the driving signal supply control unit supplies the driving signals containing the supply content that allows the load driving device to be driven with lower power consumption than in the normal driving status, independently to each of the first and the second power supply circuits.

For example, while allowing the first power supply circuit to be driven

in a normal driving status, an amount of a bias current signal (the driving signal) supplied to the second power supply circuit is reduced to less than in the normal driving status. Thereby, as compared to the conventional technology, the load driving device in the first aspect can return from the low-power driving status to the normal driving status in a shorter time, as well as the individual circuits can be driven with low power consumption.

It is desirable to appropriately set the supply content of the driving signal based on the driving status of the load. For example, when a standby time of the load is short, the supply content is set such that the returning time is as short as possible as described above. Conversely, when the standby time of the load is long, the supply content may be set so as to allow the first and the second power supply circuits to be both driven with low power. In this manner, the supply content is desirably set such that the load driving device can be driven with minimum power consumption.

Additionally, controlling the supply of the driving signal to each of the

first and the second power supply circuits to allow the load driving device to be driven with low power consumption results in low-power driving of the power supply circuits. Accordingly, the circuits receiving power from the power supply circuits can also be driven with low power.

Consequently, there can be obtained an advantageous effect that the load driving device can be efficiently driven with low power consumption.

The supply content setting unit may set the supply content by register settings, terminal settings, or the like. For example, the supply content setting unit writes a setting value for stopping supplying the driving signal or a setting value for driving in an idle status in a register. Timing of writing the setting value may be set by allowing a microcomputer to determine a driving status of the load or to analyze a driving program of the load. In the terminal settings, according to a user's setting command, there may be provided a terminal setting corresponding to each supply content, such as a jumper wire connection. The supply content setting as above is performed similarly in a driving signal supply control semiconductor device according to a seventh preferred feature of the first aspect described below.

The normal driving status means a condition in which the load driving device is not driven with low power in the standby status of the load. In the condition, supplying a control signal (an input signal) to the individual circuits of the load driving device allows the first and the second transistors to be immediately driven in a normal mode of operation, thereby enabling the load to be driven. This is also the same in the driving signal supply control semiconductor device according to the seventh preferred feature of the first aspect.

The supply content regarding the low-power driving of the load driving device includes supply stoppage of a driving signal, supply of a clock signal having a lower frequency than in the normal driving status if the driving signal is a clock signal, and supply stoppage of bias current or reduction of an amount of bias current supplied if the driving signal is a bias voltage signal, for example. In terms of the supply stoppage of bias current, the bias current supply is not completely stopped but continued in such a manner that the load driving device is driven in a lower power consumption state than in the normal driving status. Thereby, the first and the second power supply circuits are put in an idle status in which the power supply circuits can immediately return to the normal driving status as compared to the complete supply stoppage of the bias current.

In order to reduce the amount of the bias current supplied, for example, a bias current level to be supplied may be reduced, or the number of terminals of a circuit receiving the bias current may be reduced.

According to a first preferred feature of the first aspect, in the driving signal supply control semiconductor device of the first aspect, the first power supply circuit includes a DC/DC converter including at least one switching element; the second power supply circuit includes a linear regulator; the supply content set by the supply content setting unit includes a first supply content and a second supply content; and when the supply content setting unit sets the first supply content, the driving signal supply control unit stops supply of a switching signal as one of the driving signals to be supplied to the at least one switching element of the DC/DC converter to the switching element and controls a supply content of a bias voltage signal as one of the driving signals to the first and the second power supply circuits such that an amount of bias current supplied is reduced to less than in the normal driving status, whereas when the supply content setting unit sets the second supply content, the driving signal supply control unit supplies the switching signal having a lower switching frequency than in the normal driving status to the switching element and controls the supply content of the bias voltage signal to the second power supply circuit such that the amount of bias current supplied is reduced to less than in the normal driving status.

In the above semiconductor device, when the supply content setting unit sets the first supply content, the driving signal supply control unit controls the content of the bias voltage signal supplied to the first and the second power supply circuits so as to reduce the amount of the supplied bias current to less than in the normal driving status. Conversely, when the second supply content is set by the setting unit, the driving signal supply control unit supplies the lower-frequency switching signal than in the normal driving status to the switching element included in the DC/DC converter of the first power supply circuit. Additionally, the driving signal supply control unit controls the supply content of the bias voltage signal to the second power supply circuit (the linear regulator) such that the amount of the supplied bias current is reduced to less than in the normal driving status.

In other words, when the first supply content is set in the standby status of the load, the amount of the bias current supplied to the first and the second power supply circuits can be reduced to less than in the normal driving status. In addition, the switching signal supply to the first power supply circuit can be stopped. Thus, the first and the second power supply circuits can be driven with relatively low power consumption.

Conversely, when the second supply content is set, a switching frequency supplied to the switching element can be reduced to less than in the normal driving status, while the amount of the bias current supplied to the first power supply unit can be maintained at the same level as in the normal driving status. In this case, the amount of power consumption is increased than in the setting of the first supply content. However, only returning the switching frequency to a normal driving frequency enables the first power supply circuit to return to the normal driving status, thereby relatively reducing the returning time. In other words, the load driving device can be controlled to be in the idle status so as to immediately drive the load.

Accordingly, for example, the second supply content may be set in a driving program in which the load repeats the standby status and the driving status in a short time, whereas the first supply content may be set when the standby status of the load is relatively long. This enables the load driving device to be efficiently driven with low power consumption.

In order to control the supply content of the bias voltage signal such that the amount of the supplied bias current is reduced to less than in the normal driving status includes, for example, an adjustment may be made to the amount of bias current supplied to a circuit generating a bias voltage supplied to the first power supply circuit or bias current supply may be stopped. Any other controlling methods can be used as long as the methods can finally reduce the amount of the bias current supplied to the first power supply circuit. This is also the same in a driving signal supply control semiconductor device according to a third preferred feature of the first aspect described below.

According to a second preferred feature of the first aspect, in the driving signal supply control semiconductor device of the first preferred feature of the first aspect, the driving signal supply control unit includes a first switching signal generating section generating a first switching signal supplied in the normal driving status of the first power supply circuit to output the first switching signal; a second switching signal generating section generating a second switching signal having a lower frequency than the first switching signal to output the second switching signal; and a switching signal supply control section supplying the first switching signal to the switching element in the normal driving status of the first power supply circuit, the switching signal supply control section stopping supply of the first and the second switching signals to the switching element when the supply content setting unit sets the first supply content, whereas supplying the second switching signal to the switching element when the supply content setting unit sets the second supply content.

In the above semiconductor device, in the normal driving status, the switching signal supply control section supplies the first switching signal from the first switching signal generating section to the switching element. Additionally, when the supply content setting unit sets the first supply content, the switching signal supply control section stops supplying both of the first and the second switching signals to the switching element. On the other hand, when the setting unit sets the second supply content, the switching signal supply control section supplies the second switching signal from the second switching signal generating section to the switching element.

In this manner, there can be obtained mechanisms and advantageous effects equivalent to those obtained in the driving signal supply control semiconductor device of the first preferred feature of the first aspect.

According to a third preferred feature of the first aspect, in the driving signal supply control semiconductor device of the first aspect, the first power supply circuit includes a DC/DC converter including at least one switching element; the second power supply circuit includes a linear regulator; the supply content set by the supply content setting unit includes a first supply content and a second supply content; and when the supply content setting unit sets the first supply content, the driving signal supply control unit stops supply of a switching signal as one of the driving signals supplied to the at least one switching element included in the DC/DC converter to the switching element and controls a supply content of a bias voltage signal as one of the driving signals to the first and the second power supply circuits such that an amount of bias current supplied is reduced to less than in the normal driving status, whereas when the supply content setting unit sets the second supply content, the driving signal supply control unit stops supply of the switching signal to the switching element and controls the supply content of the bias voltage signal to the second power supply circuit such that the amount of the bias current supplied is reduced to less than in the normal driving status.

In the above semiconductor device, when the supply content setting unit sets the first supply content, the driving signal supply control unit controls the content of the bias voltage signal supplied to the first and the second power supply circuits to reduce the amount of the bias current supplied as compared to the normal driving status. Conversely, in the supply content setting by the supply content setting unit, the driving signal supply control unit stops the supply of the switching signal to the switching element included in the DC/DC converter of the first power supply circuit. In addition, the driving signal supply control unit controls the content of the bias voltage signal supplied to the second power supply circuit to reduce the amount of the bias current supplied less than in the normal driving status.

In other words, in the standby status of the load, when the first supply content is set, the amount of the bias current to the first and the second power supply circuits can be reduced to less than in the normal driving status of the load, and also the supply of the switching signal to the first power supply circuit can be stopped, thereby enabling the first and the second power supply circuits to be driven with relatively low power consumption. Additionally, when the second supply content is set, the switching signal supply to the switching element can be stopped while maintaining the amount of the bias current to the first power supply circuit at the same level as in the normal driving status. In this case, the amount of power consumption is increased more than in the setting of the first supply content. However, only supplying the switching signal allows the first power supply circuit to return to the normal driving status, and thus, the returning time can be relatively reduced. In short, the load driving device can be controlled to be put in an idle status in which the load can immediately be driven.

Accordingly, for example, the second supply content may be set in the driving program in which the load repeats the standby status and the driving status in a short time, whereas the first supply content may be set when the standby status of the load is relatively long. This enables the load driving device to be efficiently driven with low power consumption.

According to a fourth preferred feature of the first aspect, in the driving signal supply control semiconductor device of the first preferred feature of the first aspect, the driving signal supply control unit includes a first bias voltage outputting circuit that includes a first voltage converting section converting a first bias current signal to a first bias voltage signal to output the first bias voltage signal and a second voltage converting section converting a second bias current signal to a second bias voltage signal to output the second bias voltage signal; a second bias voltage outputting circuit having the same structure as the first bias voltage outputting circuit; a first bias voltage selecting circuit selecting the bias voltage signal supplied to the first power supply circuit in the first and the second bias voltage signals output from the first bias voltage outputting circuit; a second bias voltage selecting circuit selecting the bias voltage signal supplied to the second power supply circuit in the first and the second bias voltage signals output from the second bias voltage outputting circuit; and a bias current supply control section supplying, in the normal driving status, only the first one of the first and the second bias current signals to the first and the second voltage converting sections of the first and the second bias voltage outputting circuits, the bias current supply control section supplying only the second one of the first and the second bias current signals to the first and the second voltage converting sections of the first and the second bias voltage outputting circuits when the supply content setting unit sets the first supply content, whereas when the supply content setting unit sets the second supply content, the bias current supply control section supplies only the first one of the first and the second bias current signals to the first and the second voltage converting sections of the first bias voltage outputting circuit and supplies only the second bias current signal to the first and the second voltage converting sections of the second bias voltage outputting circuit.

In the above semiconductor device, in the normal driving status of the load, the bias current supply control section enables the first bias current signal to be supplied to the first voltage converting section of the first bias voltage outputting circuit while inhibiting the second bias current signal from being supplied to the second voltage converting section of the second bias voltage outputting circuit.

Additionally, when the supply content setting unit sets the first supply content, the bias current supply control section can inhibit the first bias current signal from being supplied to the first voltage converting section of the first bias voltage outputting circuit while allowing the second bias current signal to be supplied to the second voltage converting section of the second bias voltage outputting circuit.

Furthermore, when the supply content setting unit sets the second supply content, the bias current supply control section enables the first bias current signal to be supplied to the first voltage converting section of the first bias voltage outputting circuit while inhibiting the second bias current signal from being supplied to the second voltage converting section of the first bias voltage outputting circuit. Additionally, the bias current supply control section can inhibit the first bias current signal from being supplied to the first voltage converting section of the second bias voltage outputting circuit while allowing the second bias current signal to be supplied to the second voltage converting section of the second bias voltage outputting circuit.

In this manner, there can be obtained mechanisms and advantageous effects equivalent to those provided in the driving signal supply control semiconductor device of any one of the first to the third preferred features of the first aspect.

According to a fifth preferred feature of the first aspect, in the driving signal supply control semiconductor device of the first preferred feature of the first aspect, the driving signal supply control unit includes a first bias voltage outputting circuit that includes a first voltage converting section converting a first bias current signal to a first bias voltage signal to output the first bias voltage signal, a second voltage converting section converting a second bias current signal to a second bias voltage signal to output the second bias voltage signal, a third transistor turned on and off by a first input voltage, the third transistor supplying the first bias current signal to the first voltage converting section in an on state and stopping the supply of the first bias current signal in an off state; and a fourth transistor turned on and off by a second input voltage, the fourth transistor supplying a second bias current signal having a smaller current level than the first bias current signal to the second voltage converting section in an on state and stopping the supply of the second bias current signal in an off state; a second bias voltage outputting circuit having the same structure as the first bias voltage outputting circuit; a first bias voltage selecting circuit selecting the bias voltage signal supplied to the first power supply circuit in the first and the second bias voltage signals output from the first bias voltage outputting circuit based on the first and the second input voltages; a second bias voltage selecting circuit selecting the bias voltage signal supplied to the second power supply circuit in the first and the second bias voltage signals output from the second bias voltage outputting circuit based on the first and the second input voltages; and a bias current supply control section supplying the first and the second input voltages to driving terminals of the third and the fourth transistors of the first and the second bias voltage outputting circuits to turn on the third transistor and turn off the fourth transistor in the normal driving status, the bias current supply control section supplies the first and the second input voltages to the driving terminals of the third and the fourth transistors of the first and the second bias voltage outputting circuits to turn off the third transistor and on the fourth transistor when the supply content setting unit sets the first content, whereas when the supply content setting unit sets the second supply content, the bias current supply control section supplies the first and the second input voltages to the driving terminals of the third and the forth transistors of the first bias voltage outputting circuit to turn on the third transistor and turn off the fourth transistor and supplies the first and the second input voltages to the driving terminals of the third and the forth transistors of the second bias voltage outputting circuit to turn off the third transistor and turn on the fourth transistor.

In the above semiconductor device, in the normal driving status, the bias current supply control section can supply the first and the second input voltages to the driving terminals of the third and the fourth transistors of the first bias voltage outputting circuit to turn on the third transistor and turn off the fourth transistor, as well as can supply the first and the second input voltages to the driving terminals of the third and the fourth transistors of the second bias voltage outputting circuit to turn on the third transistor and turn off the fourth transistor. Thereby, the first bias current can be supplied to the first voltage converting section of the first bias voltage outputting circuit. Thus, controlling appropriately the first and the second input voltages enables the first bias voltage to be supplied to the first power supply circuit. Additionally, since the first bias current can be supplied to the first voltage converting section of the second bias voltage outputting circuit, the first bias voltage can be supplied to the second power supply circuit by appropriately controlling the first and the second input terminals enables.

Additionally, when the supply content setting unit sets the first supply content, the bias current supply control unit supplies the first and the second input voltages to the driving terminals of the third and the fourth transistors of the first bias voltage outputting circuit to turn off the third transistor and on the fourth transistor and also supplies the first and the second input voltages to the driving terminals of the third and the fourth transistors of the second bias voltage outputting circuit to turn off the third transistor and on the fourth transistor. Thereby, the second bias current signal having a smaller current level than the first bias current signal can be supplied to the second voltage converting section of the first bias voltage outputting circuit. Thus, controlling appropriately the first and the second input voltages enables the second bias voltage signal to be supplied to the first power supply circuit. Additionally, the second bias current signal can be supplied to the second voltage converting section of the second bias voltage outputting circuit. Thus, the second bias voltage signal can be supplied to the second power supply circuit by appropriately controlling the first and the second input voltages.

Additionally, when the supply content setting unit sets the second supply content, the bias current supply control unit can supply the first and the second input voltages to the driving terminals of the third and the fourth transistors of the first bias voltage outputting circuit to turn on the third transistor and turn off the fourth transistor and also can supply the first and the second input voltages to the driving terminals of the third and the fourth transistors of the second bias voltage outputting circuit to turn off the third transistor and turn on the fourth transistor. Thereby, the first bias current signal can be supplied to the first voltage converting section of the first bias voltage outputting circuit. Thus, controlling appropriately the first and the second input voltages enables the first bias voltage signal to be supplied to the first power supply circuit. Additionally, the second bias current signal having a smaller current level than the first bias current signal can be supplied to the second voltage converting section of the second bias voltage outputting circuit. Thus, the second bias voltage signal can be supplied to the second power supply circuit by appropriately controlling the first and the second input voltages.

In this manner, there can be obtained mechanisms and advantageous effects equivalent to those provided in the driving signal supply control semiconductor device of any one of the first to the third preferred features of the first aspect.

According to a sixth preferred feature of the first aspect, in the driving signal supply control semiconductor device of the first aspect, the load driving device further includes a current detecting circuit detecting an amount of current flowing through the load; and, based on the supply content set by the supply content setting unit, the driving signal supply control unit controls a supply content of a driving signal supplied to the current detecting circuit such that the current detecting circuit stops operating or is driven with lower power consumption than in the normal driving status.

In the above semiconductor device, when the supply content setting unit sets a predetermined supply content according to the standby status of the load, the driving signal supply control unit controls such that the supply content of the driving signal supplied to the current detecting circuit becomes a content representing operation stoppage of the current detecting circuit or a content representing driving of the current detecting circuit with lower power than in the normal driving status of the circuit.

For example, in the standby status of the load, when the supply content setting unit sets the supply content representing lower-power driving than in the normal driving status, the driving signal supply control unit controls the supply content of the bias voltage or the like supplied to the current detecting circuit so as to reduce the amount of the bias current supplied to the current detecting circuit to less than in the normal driving state.

Thereby, in the standby status of the load, the supply of the driving signal to the current detecting circuit can be controlled in addition to control of the supply of the driving signals to the first and the second power supply circuits. Therefore, power consumption of the load driving device can be further reduced.

According to the seventh preferred feature of the first aspect, in the driving signal supply control semiconductor device of the first preferred feature of the first aspect, the load driving device further includes a current detecting circuit detecting an amount of current flowing through the load; and when the supply content setting unit sets either the first or the second supply content, the driving signal supply control unit allows a bias voltage signal as one of the driving signals to the current detecting circuit at a potential where no bias current signal flows.

In the above semiconductor device, when the first or the second supply content is set by the supply content setting unit, the driving signal supply control unit supplies the bias voltage signal as one of the driving signals to the current detecting circuit at the potential where no bias current signal flows.

Thereby, for example, in the standby status of the load, power consumption of the current detecting circuit can be reduced, resulting in a further reduction in the amount of power consumption of the load driving device.

Meanwhile, in order to provide the above advantage, according to a second aspect of the invention, there is provided a driving signal supply control semiconductor device. The driving signal supply control semiconductor device of the second aspect includes a load driving device that includes (i) an H-bridge circuit including a high-side first transistor and a low-side second transistor, the transistors being electrically connected to a load as an object to be driven and being turned on or off to energize or de-energize the load; (ii) a first driving circuit driving the first transistor; (iii) a second driving circuit driving the second transistor; (iv) a first power supply circuit supplying driving power to the first driving circuit; (v) a second power supply circuit supplying driving power to the second driving circuit; (vi) at least a first bias voltage supply circuit and a second bias voltage supply circuit, the first bias voltage supply circuit supplying a bias voltage to the first power supply circuit and the second bias voltage supply circuit supplying a bias voltage to the second power supply circuit; (vii) a supply content setting unit setting a supply content of each of driving signals regarding low power driving of the load driving device according to a standby status of the load; and (viii) a driving signal supply control unit controlling supply of the driving signals to the first and the second power supply circuits, the driving signal supply control unit controlling independently contents of the driving signals supplied to each of the first and the second bias voltage supply circuits such that the load driving device is driven with lower power consumption than in a normal driving status of the load driving device, based on the supply content set by the supply content setting unit.

In the above semiconductor device, according to the standby status of the load, the supply content setting unit sets a predetermined supply content. Then, based on the set supply content, the driving signal supply control unit generates and supplies independently the driving signal of the supply content regarding lower-power driving of the load driving device than in the normal driving status to each of the first and the second bias voltage supply circuits.

For example, there are generated driving signals having a supply content in which the bias voltage supplied to the second power supply circuit is reduced to less than in the normal driving status while supplying a normal bias voltage to the first power supply circuit. Then, the generated driving signals are supplied to the first and the second bias voltage supply circuits. As compared to the conventional technology, the load driving device can return to the normal driving status from the low-power driving status in a shorter time and also the respective circuits can also be driven with lower power consumption.

In the setting of the supply content of the driving signal, desirably, an appropriate content is set based on the driving status of the load. For example, when the standby time of the load is short, there is set a supply content that reduces the returning time as much as possible, as described above. Conversely, in the case of the long standby time of the load, the set supply content represents driving of the load driving device with power consumption as low as possible.

Furthermore, controlling the driving signals supplied to the first and the second bias voltage supply circuits so as to drive the load driving device with low power ultimately results in low-power driving of the first and the second power supply circuits. This enables the circuits receiving power from the respective power supply circuits to also be driven with low power consumption.

Therefore, the load driving device can be efficiently driven with low power consumption.

According to a first preferred feature of the second aspect of the invention, in the driving signal supply control semiconductor device of the second aspect, the first bias voltage supply circuit includes a first voltage converting section converting a first bias current signal to a first bias voltage signal to output the first bias voltage signal, a second voltage converting section converting a second bias current signal to a second bias voltage signal to output the second bias voltage signal, a third transistor turned on or off by a first input voltage, the third transistor supplying the first bias current signal to the first voltage converting section in an on state and stopping the supply of the first bias current signal in an off state, a fourth transistor turned on or off by a second input voltage, the fourth transistor supplying the second bias current signal having a smaller current level than the first bias current signal to the second voltage converting section in an on state and stopping the supply of the second bias current signal in an off state, and a first bias voltage selecting section selecting the bias voltage signal supplied to the first power supply circuit in the first and the second bias voltage signals output from the first bias voltage outputting circuit based on the first and the second input voltages; the second bias voltage supply circuit includes a first voltage converting section converting a first bias current signal to a first bias voltage signal to output the first bias voltage signal, a second voltage converting section converting a second bias current signal to a second bias voltage signal to output the second bias voltage signal, a third transistor turned on and off by a first input voltage, the third transistor supplying the first bias current signal to the first voltage converting section in an on state and stopping the supply of the first bias current signal in an off state, a fourth transistor turned on and off by a second input voltage, the fourth transistor supplying a second bias current signal having a smaller current level than the first bias current signal to the second voltage converting section in an on state and stopping the supply of the second bias current signal in an off state, and a second bias voltage selecting section selecting the bias voltage signal supplied to the second power supply circuit in the first and the second bias voltage signals output from the second bias voltage outputting circuit based on the first and the second input voltages; the supply content set by the supply content setting unit includes a first supply content and a second supply content; and, in the normal driving status, the driving signal supply control unit supplies the first and the second input voltages to driving terminals of the third and the fourth transistors of the first and the second bias voltage supply circuits to turn on the third transistor and turn off the fourth transistor in the normal driving status, the driving signal supply control unit supplying the first and the second input voltages to the driving terminals of the third and the fourth transistors of the first and the second bias voltage supply circuits to turn off the third transistor and turn on the fourth transistor when the supply content setting unit sets the first supply content, whereas supplying the first and the second input voltages to the driving terminals of the third and the fourth transistors of the first bias voltage supply circuit to turn on the third transistor and turn off the fourth transistor and supplying the first and the second input voltages to the driving terminals of the third and the fourth transistors of the second bias voltage supply circuit to turn off the third transistor and turn on the fourth transistor when the supply content setting unit sets the second supply content.

In the above semiconductor device, in the normal driving status, the driving signal supply control unit can supply the first and the second input voltages for turning on the third transistor and turning off the fourth transistor to the driving terminals of the third and the fourth transistors of the first and the second bias voltage outputting circuits. This allows the first bias current to be supplied to the first voltage converting section of each of the first and the second bias voltage outputting circuits. Thus, controlling appropriately the first and the second input voltages enables the first bias voltage to be supplied to each of the first and the second power supply circuits.

Additionally, when the supply content setting unit sets the first supply content, the driving signal supply control unit can supply the first and the second input voltages for turning off the third transistor and turning on the fourth transistor to the driving terminals of the third and the fourth transistors of each of the first and the second bias voltage outputting circuits. This allows the second bias current having a smaller current level than the first bias current signal to be supplied to the second bias voltage converting section of each of the first and the second bias voltage outputting circuits. Thus, controlling appropriately the first and the second input voltages enables the second bias voltage to be supplied to the second power supply circuit.

Additionally, in the case of setting the second supply content by the setting unit, the driving signal supply control unit can supply the first and the second input voltages for turning on the third transistor and turning off the fourth transistor to the driving terminals of the third and the fourth transistors of the first bias voltage outputting circuit and also can supply the first and the second input voltages for turning off the third transistor and turning on the fourth transistor to the driving terminals of the third and the fourth transistors of the second bias voltage outputting circuit. Thereby, the first bias current signal can be supplied to the first voltage converting section of the first bias voltage outputting circuit, as well as the second bias current having a smaller current level than the first bias current signal can be supplied to the second bias voltage converting section of the second bias voltage outputting circuit. Thus, controlling appropriately the first and the second input voltages enables the first bias voltage to be supplied to the first power supply circuit and also enables the second bias voltage to be supplied to the second power supply circuit.

In this manner, there can be obtained mechanisms and advantageous effects equivalent to those obtained in the driving signal supply control semiconductor device of the second aspect.

Furthermore, according to a second preferred feature of the second aspect of the invention, in the driving signal supply control semiconductor device of the first preferred feature of the second aspect, the load driving device further includes a current detecting circuit detecting an amount of current flowing through the load and a third bias voltage supply circuit supplying a bias voltage to the current detecting circuit; and the driving signal supply control unit controls to stop supply of the driving signals to the third bias voltage supply circuit when the supply content setting unit sets the first supply content or the second supply content.

In the above semiconductor device, in the setting of the first or the second supply content by the supply content setting unit, the driving signal supply control unit stops supply of the driving signals (such as a bias current signal) to the third bias voltage supplying current.

This can reduce power consumption of the current detecting circuit in the standby status of the load, for example. Consequently, power consumption of the load driving device can be further reduced.

### BRIEF DESCRIPTION OF THE DRAWINGS

The invention will be described with reference to the accompanying drawings, wherein like numbers reference like elements.

FIG. 1 is a block diagram showing a structure of a motor driving device 1 according to a first embodiment of the invention.

FIG. 2 is a block diagram showing an internal structure of a driving signal supply control circuit 20 and a power supply circuit 30.

FIG. 3 is a diagram showing an example of the relationship between respective output modes and supply controlling contents.

FIG. 4A is a block diagram showing an internal structure of a first driving signal supply control circuit 21.

FIG. 4B is a diagram showing a part of a circuit that receives a voltage-boosting clock signal

FIG. 5 is a block diagram showing internal structures of a second driving signal supply control circuit 22 and a bias voltage supplying section 33.

FIG. 6 is a block diagram showing an internal structure of a first bias voltage outputting circuit 22a.

FIGS. 7A and 7B are diagrams showing respective internal structures of first and second bias voltage selecting circuits 34 and 36.

FIG. 8 is a block diagram showing a structure of a transistor driving circuit 40.

FIG. 9 is a diagram showing detailed structures of an H-bridge circuit 50 and a current detecting circuit 60.

### DESCRIPTION OF EXEMPLARY EMBODIMENTS

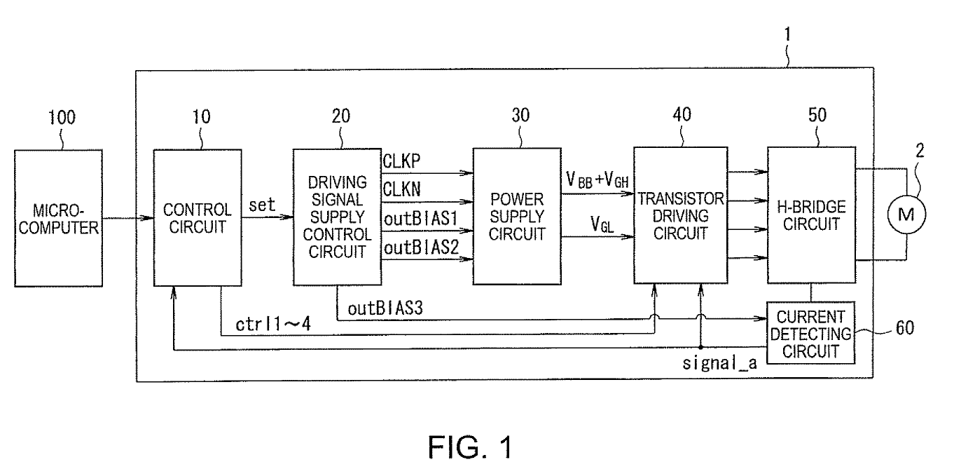

Embodiments of the invention will be described with reference to the drawings. FIGS. 1 to 9 are diagrams showing a driving signal supply control semiconductor device according to an embodiment of the invention.

In the present embodiment, a motor driving device is applied to the driving signal supply control semiconductor device of the embodiment. The motor driving device includes an H-bridge circuit that controls driving of the motor.

First, a structure of a motor driving device 1 according to the embodiment will be described with reference to FIG. 1. FIG. 1 is a block diagram showing a structure of the motor driving device 1.

As shown in FIG. 1, the motor driving device 1 includes a control circuit 10, a driving signal supply control circuit 20, a power supply circuit 30, a transistor driving circuit 40, an H-bridge circuit 50, and a current detecting circuit 60.

The control circuit 10 includes a serial interface circuit to be connected to an external microcomputer 100 (hereinafter referred to as “micon 100”). In response to a command from the micon 100, the control circuit 10 generates various kinds of control signals (such as signals “set” and “ctrl”) for controlling driving of a motor 2 to output the control signals to relevant circuits. In addition, the control circuit 10 sets a supply content (a supply mode) of a driving signal supplied to the power supply circuit 30 in an internal register to output a setting signal set indicating the set content to the driving signal supply control circuit 20.

The supply mode to be set in the embodiment includes 4 supply modes: a normal mode corresponding to a normal driving status of the motor 2; a sleep mode corresponding to low-power driving of the motor 2; and an idle mode 1 and an idle mode 2 corresponding to idle driving of the motor 2.

The setting signal set is a signal represented by a sequence of 9 bits including an xsleep bit corresponding to the sleep mode, an IDLE 1 bit corresponding to the idle mode 1, an IDLE 2 bit corresponding to the idle mode 2, and cctrl 1 to 6 bits as control bits of bias current corresponding to the respective modes. A bit value “0” is represented by a signal having low level (hereinafter referred to as “L level”), whereas a bit value “1” is represented by a signal having high level (hereinafter referred to as “H level”).

Based on the content of the setting signal set, the driving signal supply control circuit 20 supplies a driving signal containing a supply content corresponding to each of the supply modes set in the register to various power supply circuits included in the power supply circuit 30 and the current detecting circuit 60.

Then, based on the driving signals from the driving signal supply control circuit 20, the power supply circuit 30 drives the various power supply circuits included therein to supply driving power to the transistor driving circuit 40.

Based on a control signal from the control circuit 10, the transistor driving circuit 40 drives independently high-side and low-side transistors included in the H-bridge circuit 50.

The H-bridge circuit 50 includes DMOSFETs Q1, Q3 as the high-side transistors and DMOSFETs Q2, Q4 as the low-side transistors. The high-side transistors Q1 and Q3 are connected to the low-side transistors Q2 and Q4 to form an H-bridge configuration. The transistor driving circuit 40 controls driving of the high-side transistors Q1, Q3 and the low-side transistors Q2, Q4 such that the high-side and the low-side transistors are independently driven, thereby allowing the DC motor 2 as a driving object to be rotated forwardly or reversely, braked, or the like according to respective control contents of the transistor driving circuit 40.

Based on the driving signal from the driving signal supply control circuit 20, the current detecting circuit 60 detects a level of electric current flowing through the motor 2 to output a current detection signal #a as a result of the detection to the control circuit 10 or the like.

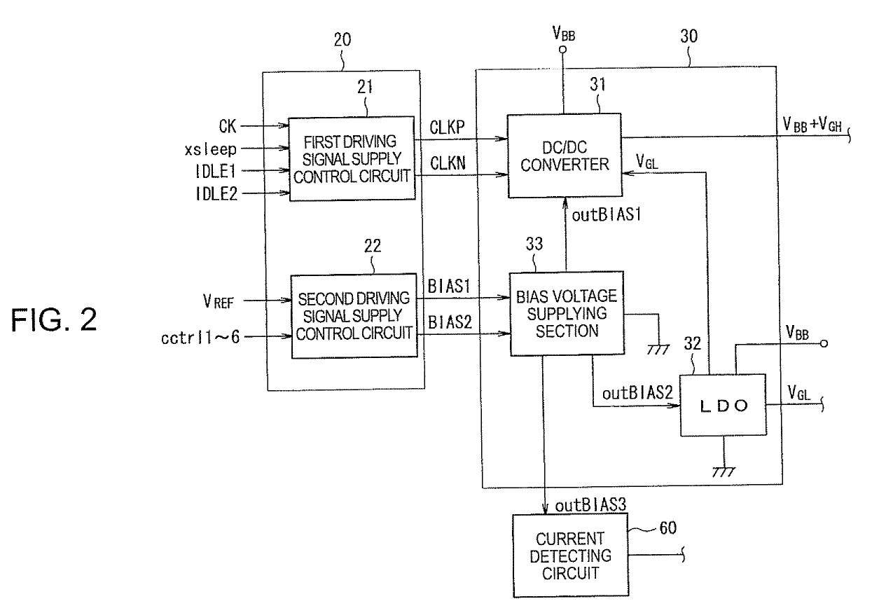

Next, with reference to FIG. 2, a description will be given of internal structures of the driving signal supply control circuit 20 and the power supply circuit 30.

FIG. 2 is a block diagram showing the internal structures of the driving signal supply control circuit 20 and the power supply circuit 30.

As shown in FIG. 2, the driving signal supply control circuit 20 includes a first driving signal supply control circuit 21 and a second driving signal supply control circuit 22.

Additionally, in FIG. 2, the power supply circuit 30 includes a DC/DC converter 31, a low dropout regulator (LDO) 32, and a bias voltage supplying section 33. The DC/DC converter 31 is a capacitor charge pump converter and supplies driving power to a high-side transistor driving circuit in the transistor driving circuit 40. The LDO 32 is a linear regulator that supplies driving power to a low-side transistor driving circuit in the transistor driving circuit 40. The bias voltage supplying section 33 supplies bias voltage signals outBIAS 1, 2, and 3 to the DC/DC converter 31, the LDO 32, and the current detecting circuit 60.

The first driving signal supply control circuit 21 controls supply of a voltage boosting clock signal (a switching signal) as one of driving signals supplied to at least one switching element included in the DC/DC converter 31, based on a set supply mode.

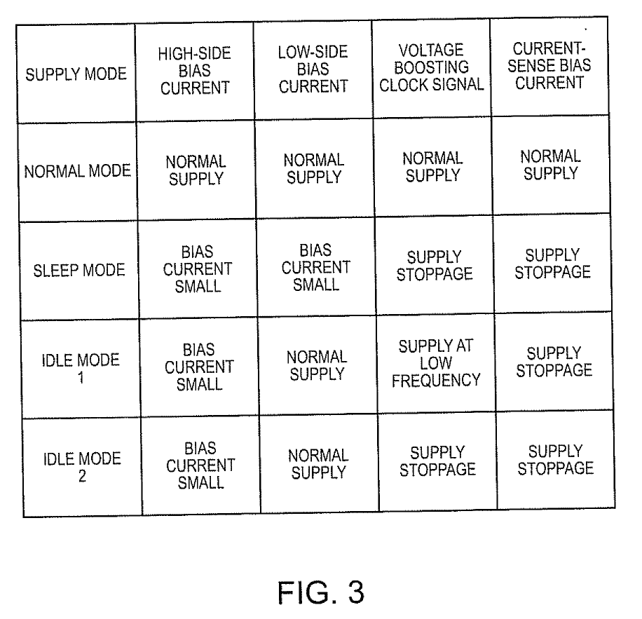

In the embodiment, as shown in FIG. 3, when the set supply mode includes the sleep mode and the idle mode 2, the first driving signal supply control circuit 21 stops supply of the voltage boosting clock signal to the switching element. When the idle mode 1 is set as the supply mode, the first driving signal supply control circuit 21 supplies a voltage boosting clock signal having a low frequency to the switching element. The low-frequency voltage boosting clock signal has a lower frequency than the voltage boosting clock signal in a normal driving status of the motor 2.

FIG. 3 is a diagram showing an example of a relationship between the supply modes and supply control contents.

Based on each set supply mode, the second driving signal supply control circuit 22 controls supply of a driving signal to the bias voltage supplying section 33 that supplies bias voltage signals for supplying bias current to the DC/DC converter 31, the LDO 32, and the current detecting circuit 60.

Specifically, as shown in FIG. 3, when the sleep mode is set as the supply mode, the second driving signal supply control circuit 22 stops supply of the bias voltage signals to the DC/DC converter 31 and the LDO 32, and also stops supply of the bias voltage signal to the current detecting circuit 60 to provide current control such that no bias current signal flows through the circuits. Meanwhile, upon setting of the idle modes 1 and 2 as the supply modes, the bias voltage signal supplied to the DC/DC converter 31 is made equal to that in the normal driving status of the motor 2, and the bias voltage signal to the LDO 32 is supplied such that an amount of the bias current supplied is reduced to less than in the normal driving status of the motor 2. Additionally, the second driving signal supply control circuit 22 stops the supply of the bias voltage signal to the current detecting circuit 60 to inhibit the bias current from flowing through the current detecting circuit 60.

The DC/DC converter 31 uses a known capacitor charge pump system (also referred to as “a switched capacitor system”). The DC/DC converter 31 receives an input signal corresponding to a driving voltage VBB of the motor 2 and adds the voltage VBB to a driving voltage VGH of the high-side transistors Q1 and Q3 included in the H-bridge circuit 50 to output a signal having a boosted voltage VBB+VGH.

The LDO 32 is a known linear regulator and includes an output transistor, an operational amplifier, a reference voltage source, and a voltage dividing resistance. The output transistor is connected between input and output voltage terminals and the operational amplifier compares an output voltage with a reference voltage to control an on resistance of the output transistor by using an output of the operational amplifier so as to maintain the output voltage at a predetermined level. In this case, the output transistor is not pulse-driven but continuously driven.

The bias voltage supplying section 33 supplies the bias voltage signal according to the set supply mode independently to each of the DC/DC converter 31, the LDO 32, and the current detecting circuit 60, based on each driving signal from the second driving signal supply control circuit 22.

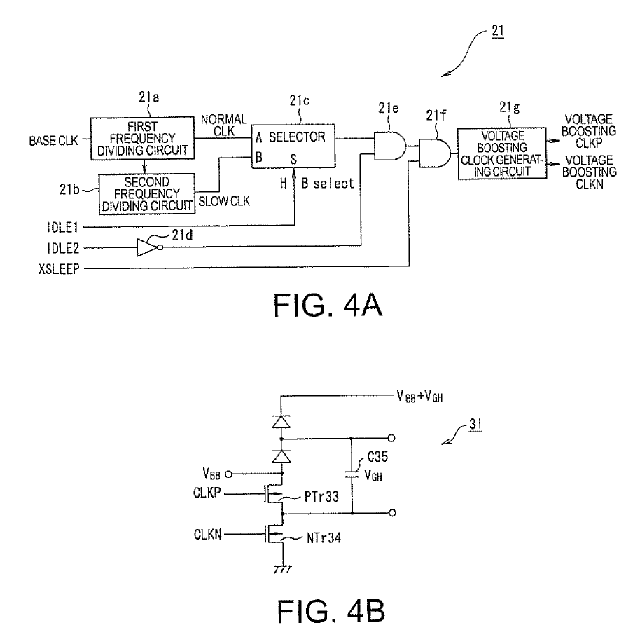

Next, an internal structure of the first driving signal supply control circuit 21 will be described with reference to FIGS. 4A and 4B.

FIG. 4A is a block diagram showing the internal structure of the first driving signal supply control circuit 21, and FIG. 4B is a diagram showing a part of a circuit receiving the voltage boosting clock signal.

As shown in FIG. 4A, the first driving signal supply control circuit 21 includes a first frequency dividing circuit 21a, a second frequency dividing circuit 21b, a selector 21c, a first AND circuit 21e, a second AND circuit 21f, and a voltage boosting clock generating circuit 21g.

The first frequency dividing circuit 21a divides a frequency of a basic CLK signal supplied from a not-shown oscillator to generate a first clock signal having a switching frequency corresponding to the normal driving status of the motor 2 so as to input the first clock signal to an input terminal A of the selector 21c.

The second frequency dividing circuit 21b divides a frequency of the first clock signal (a normal CLK) to generate a second clock signal (a slow CLK) having a lower frequency than the switching frequency of the first clock signal so as to input the second clock signal to an input terminal B of the selector 21c.

When a signal corresponding to the IDLE 1 bit of a setting signal set input to a select signal input terminal S (hereinafter referred to as “signal IDLE 1”) is an L-level signal, the selector 21c selects the first clock signal to input the first clock signal to a first input terminal of the first AND circuit 21e. In a case of the signal IDLE 1 of H level, the selector 21c selects the second clock signal to input the signal to the first input terminal of the first AND circuit 21e.

A NOT circuit 21d reverses a level of a signal corresponding to the IDLE 2 bit of the setting signal set (hereinafter referred to as “signal IDLE 2”) to input to a second input terminal of the first AND circuit 21e. In other words, when the signal IDLE 2 is at H level, the IDLE 2 is converted to an L-level signal to be output, whereas an L-level signal IDLE 2 is converted to an H-level signal to be output.

The first AND circuit 21e inputs a signal having a level corresponding to an AND result between the input signals of the first and the second input terminals to a first input terminal of the second AND circuit 21f. Specifically, when the IDLE 2 is an H level signal, an output of the first AND circuit 21e is necessarily at L level, whereas the IDLE 2 is at L level, a signal of the same level as that of the clock signal selected by the selector 21c is output.

The second AND circuit 21f inputs a signal at a level corresponding to an AND result between a signal having a level corresponding to the AND result input to the first input terminal of the circuit 21f from the first AND circuit 21e and a signal corresponding to the xsleep bit of the setting signal set (hereinafter referred to as “signal xsleep”) input to a second input terminal of the circuit 21f to the voltage boosting clock generating circuit 21g. Specifically, when the signal xsleep is at H level, the signal input from the first AND circuit 21e as it is is input to the voltage boosting clock generating circuit 21g. In a case of an L-level signal xsleep, an output from the second AND circuit 21f is necessarily at L level.

The voltage boosting clock generating circuit 21g uses a signal having a voltage level converted so as to have the same phase as that of the input signal as a voltage boosting clock signal CLKP for a P-channel MOSFET. Additionally, the voltage boosting clock generating circuit 21g generates a signal by reversing the input signal to use the signal as a voltage boosting clock signal CLKN for an N-channel MOSFET. The signals CLKP and CLKN are output to relevant transistors as described below.

Specifically, as shown in FIG. 4B, the DC/DC converter 31 includes a PTr 33 (the P-channel MOSFET) and an NTr 34 (the N-channel MOSFET) as switching elements. Thus, the voltage boosting clock generating circuit 21g supplies the voltage boosting clock signal CLKP to a gate terminal of the PTr33 and supplies the voltage boosting clock signal CLKN to a gate terminal of the NTr 34. Thereby, the voltage boosting clock generating circuit 21g controls on and off of the PTr 33 and the NTr 34 to charge a capacitor C35 connected in parallel to the power voltage VGH so as to allow potentials at opposite ends of the capacitor C35 to be VGH. Then, the capacitor C35 is serially connected to the power voltage VBB to boost to VBB+VGH. In the present embodiment, a comparator monitors an output voltage of the DC/DC converter to allow the converter to perform a clock-signal switching operation or to stop the converter from operating so as to stably maintain the VBB+VGH voltage level, although not shown in the drawing.

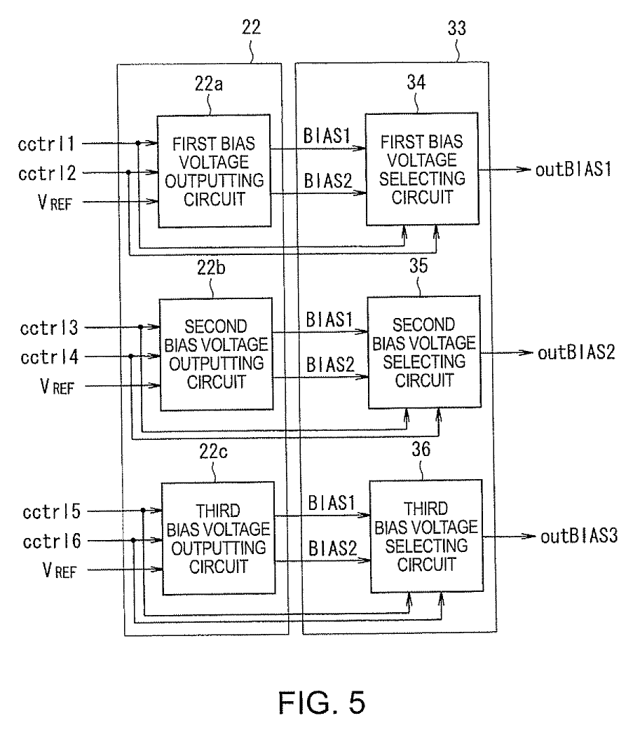

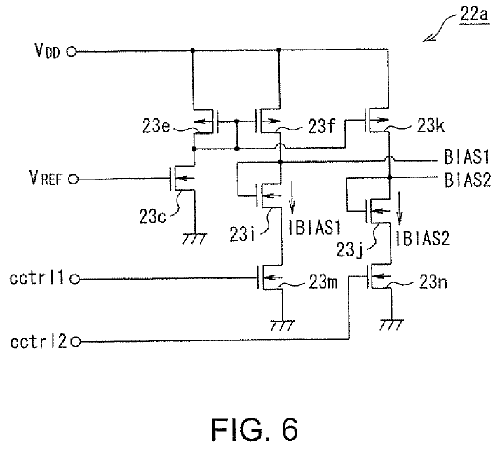

Next will be described an internal structure of the second driving signal supply control circuit 22, with reference to FIGS. 5 and 6.

FIG. 5 is a block diagram showing the internal structures of the second driving signal supply control circuit 22 and the bias voltage supplying section 33. FIG. 6 is a block diagram showing an internal structure of a first bias voltage outputting circuit 22a.

As shown in FIG. 5, the second driving signal supply control circuit 22 includes the first bias voltage outputting circuit 22a, a second bias voltage outputting circuit 22b, and a third bias voltage outputting circuit 22c.

Furthermore, as in FIG. 5, the bias voltage supplying section 33 includes a first bias voltage selecting circuit 34 supplying a bias voltage signal outBIAS 1 to the DC/DC converter 31, a second bias voltage selecting circuit 35 supplying a bias voltage signal outBIAS 2 to the LDO 32, and a third bias voltage selecting circuit 36 supplying a bias voltage signal outBIAS 3 to the current detecting circuit 60.

The first bias voltage outputting circuit 22a supplies the bias voltage signal BIAS 1 or BIAS 2 to the first bias voltage selecting circuit 34 or stops the supply of the signals BIAS 1 and BIAS 2 based on signals of cctrl 1 and 2 bits in setting signals set from the control circuit 10 (hereinafter referred to as “signals cctrl 1 and 2”) and a reference voltage VREF from a not-shown reference voltage generating circuit.

The second bias voltage outputting circuit 22b supplies the bias voltage signal BIAS 1 or BIAS 2 to the second bias voltage selecting circuit 35 or stops the supply of the signals BIAS 1 and BIAS 2 based on signals of cctrl 3 and 4 bits in setting signals set from the control circuit 10 (hereinafter referred to as “signals cctrl 3 and 4”) and the reference voltage VREF from the not-shown reference voltage generating circuit.

The third bias voltage outputting circuit 22c supplies the bias voltage signal BIAS 1 or BIAS 2 to the third bias voltage selecting circuit 36 or stops the supply of the signals BIAS 1 and BIAS 2 based on signals of cctrl 5 and 6 bits in setting signals set from the control circuit 10 (hereinafter referred to as “signals cctrl 5 and 6”) and the reference voltage VREF from the not-shown reference voltage generating circuit.

The first bias voltage selecting circuit 34 selects one of the bias voltage signals BIAS 1 and BIAS 2 input from the first bias voltage outputting circuit 22a to supply to the DC/DC converter 31 based on the signals cctrl 1 and cctrl 2 from the control circuit 10.

The second bias voltage selecting circuit 35 selects one of the bias voltage signals BIAS 1 and BIAS 2 from the second bias voltage outputting circuit 22b to supply to the LDO 32 based on the signals cctrl 3 and cctrl 4 from the control circuit 10.

The third bias voltage selecting circuit 36 selects one of the bias voltage signals BIAS 1 and BIAS 2 from the third bias voltage outputting circuit 22c to supply to the current detecting circuit 60 or does not supply either of the signals based on the signals cctrl 5 and cctrl 6 from the control circuit 10.

Next will be described a structure of the first bias voltage outputting circuit 22a, with reference to FIG. 6.

FIG. 6 is a diagram showing the structure of the first bias voltage outputting circuit 22a.

As shown in FIG. 6, the first bias voltage outputting circuit 22a includes P-channel field-effect transistors (hereinafter referred to as “PTrs”) 23e, 23f, and 23k and N-channel field-effect transistors (hereinafter referred to as “NTrs”) 23c, 23i, 23j, 23m, and 23n.

A source terminal of the NTr 23c is electrically connected to a ground node where a ground potential is 0 v. Additionally, a drain terminal of the NTr 23c is electrically connected to a drain terminal of the PTr 23e. The reference voltage VREF from the not-shown reference voltage supply circuit is applied to a gate terminal of the NTr 23c.

Gate terminals of the PTrs 23e, 23f, and 23k are electrically connected to each other. The drain terminal of the NTr 23e is electrically connected to a point connecting the gate terminals so as to form a current mirror circuit. A source terminal of each of the PTrs 23e, 23f, and 23k is electrically connected to a power node where a power voltage VDD is supplied. A drain terminal of the PTr 23f is electrically connected to a drain terminal of the NTr 23i, and a drain terminal of the PTr 23k is electrically connected to a drain terminal of the NTr 23j. When the NTr 23c is turned on by applying the voltage VREF, bias current signals IBIAS 1 and IBIAS 2 flow through the NTrs 23i and 23j via the PTrs 23f and 23k.

In this case, an amount of electric current of each of the bias current signals IBIAS 1 and IBIAS 2 is determined by a transistor size ratio of the PTrs 23f and 23k relative to the PTr 23e (a current supply capacity ratio).

In the embodiment, the PTr 23f has a transistor size of a larger current supply capacity than that of the PTr 23k to allow the bias current signal IBIAS 1 to be larger than the IBIAS 2. Specifically, the transistor sizes (the current supply capacities) of the PTr 23f and the PTr 23k are determined such that the bias current signal IBIAS 1 satisfies an amount of electric current required in the normal driving status of the motor driving device 1 and the bias current signal IBIAS 2 satisfies an amount of electric current flown in the low-power driving status of the device.

A drain terminal and a source terminal, respectively, of the NTr 23m are electrically connected to a source terminal of the NTr 23i and a ground node, respectively. A gate terminal of the NTr 23m receives the signal cctrl 1 (a voltage signal) from the control circuit 10. The signal cctrl 1 controls on and off of the NTr 23m. When the cctrl 1 is at H level, the NTr 23m is turned on to flow the IBIAS 1. Accordingly, the bias voltage signal BIAS 1 having a voltage level corresponding to the amount of electric current of the IBIAS 1 is output from an output terminal 1 of the NTr 23m electrically connected to the source terminal of the NTr 23i. The signal cctrl 1 of L level allows the NTr 23m to be turned off, whereby the IBIAS 1 does not flow.

A drain terminal and a source terminal, respectively, of the NTr 23n are electrically connected to a source terminal of the NTr 23j and a ground node, respectively. A gate terminal of the NTr 23n receives the signal cctrl 2 (a voltage signal) from the control circuit 10. The signal cctrl 2 controls on and off of the NTr 23n, in which the cctrl 2 signal of H level turns on the NTr 23n to allow the IBIAS 2 to flow through. Accordingly, the bias voltage signal BIAS 2 having a level corresponding to the amount of electric current of the IBIAS 2 is output from an output terminal 2 of the NTr 23n electrically connected to the source terminal of the NTr 23j. The signal cctrl 2 having L level turns off the NTr 23n, thereby stopping the IBIAS 2 from flowing through.

The output terminals 1 and 2 are electrically connected to two transmission gates included in the first bias voltage selecting circuit 34 at a rear stage.

While the second and third bias voltage outputting circuits 22b and 22c, respectively, output the bias voltage signals to the second and the third bias voltage selecting circuits 35 and 36, respectively, the circuits 22b and 22c have the same structure as that of the first bias voltage outputting circuit 22a. On the other hand, final output destinations of those circuits are different among them, and thus, characteristics of the transistors used can vary depending on performance of circuits as the output destinations.

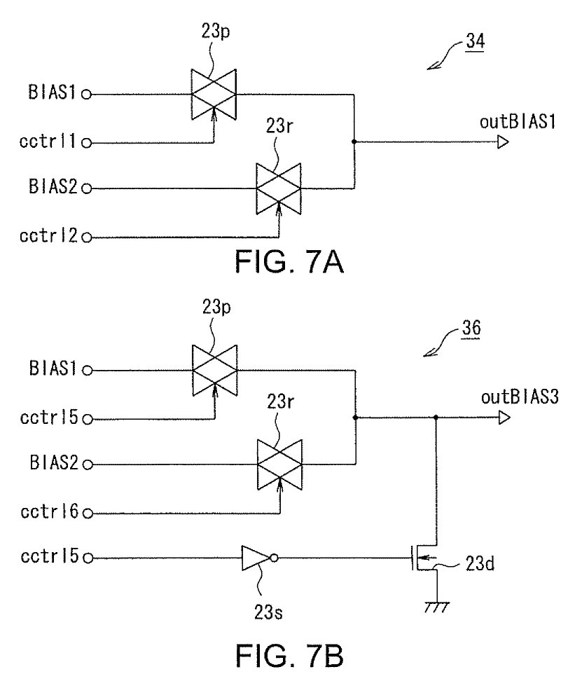

Next will be described a structure of the first bias voltage selecting circuit 34, with reference to FIGS. 7A and 7B.

FIG. 7A is a diagram showing a structure of the first bias voltage selecting circuit 34, and FIG. 7B is a structure of the third bias voltage selecting circuit 36.

The first bias voltage selecting circuit 34 includes a first transmission gate 23p and a second transmission gate 23r, as shown in FIG. 7A.

The bias voltage outputting circuit 22a inputs the bias voltage signal BIAS 1 to an input terminal of the first transmission gate 23p, and the control circuit 10 inputs the signal cctrl 1 to a control signal input terminal of the gate 23p. The first transmission gate 23p is turned off by the signal cctrl 1 of L level to block the signal BIAS 1, while being turned on by the signal cctrl 1 of H level to output the BIAS 1 from an output terminal of the gate 23p.

An input terminal of the second transmission gate 23r receives the bias voltage signal BIAS 2 input from the first bias voltage outputting circuit 22a, and a control signal input terminal of the gate 23r receives the signal cctrl 2 input from the control circuit 10. The signal cctrl 2 of L level turns off the second transmission gate 23r to block the signal BIAS 2, whereas the signal cctrl 2 of H level turns on the gate 23r to output the signal BIAS 2 from an output terminal of the gate 23r.

The output terminal of the first transmission gate 23p is electrically connected to the output terminal of the second transmission gate 23r. An output terminal 3 is disposed at a point connecting the output terminals of the gates 23p and 23r to output the bias voltage signal BIAS 1 or BIAS 2 as the outBIAS 1 to the DC/DC converter 31.

The second bias voltage selecting circuit 35 has the same circuit structure as that of the first bias voltage selecting circuit 34. Based on the signals cctrl 3 and cctrl 4 output from the control circuit 13, the second bias voltage selecting circuit 35 selects one of the bias voltage signals BIAS 1 and BIAS 2 input from the second bias voltage outputting circuit 22b to output the selected signal as the outBIAS 2 to the LDO 32.

As shown in FIG. 7B, the third bias voltage selecting circuit 36 includes the first transmission gate 23p, the second transmission gate 23r, a NOT circuit 23s, and an NTr 23d.

In short, the third bias voltage selecting circuit 36 is formed by adding the NOT circuit 23s and the NTr 23d to the first bias voltage selecting circuit 34.

The bias voltage signal BIAS 1 from the third bias voltage outputting circuit 22c is input to the input terminal of the first transmission gate 23p, and the signal cctrl 5 from the control circuit 10 is input to the control signal input terminal of the gate 23p. The BIAS 1 is blocked by the signal cctrl 5 of L level and is output by the cctrl 5 of H level from the output terminal of the gate 23p.

The bias voltage signal BIAS 2 from the third bias voltage outputting circuit 22c is input to the input terminal of the second transmission gate 23r, and the signal cctrl 6 from the control circuit 10 is input to the control signal input terminal of the gate 23r. The BIAS 2 is blocked by the signal cctrl 6 of L level and is output by the signal cctrl 6 of H level from the output terminal of the gate 23r.

A drain terminal of the NTr 23d is electrically connected to the output terminal 3 where the output terminal of the first transmission gate 23p is electrically connected to the output terminal of the second transmission gate 23r. A source terminal of the NTr 23d is electrically connected to a ground node, and a gate terminal of the Ntr 23d is electrically connected to an output terminal of the NOT circuit 23s.

The signal cctrl 5 from the control circuit 10 is input to an input terminal of the NOT circuit 23s. The NOT circuit 23s reverses the level of the signal cctrl 5 to input the signal to the gate terminal of the NTr 23d.

Accordingly, when the signal cctrl 5 having L level is input to the NOT circuit 23s, the signal cctrl 5 is reversed from L level to H level, and then, the H-level signal is input to the gate terminal of the NTr 23d. Thereby, the NTr 23d is turned on and the signal outBIAS 3 reaches the L level (a ground potential) regardless of a content of the signal cctrl 6. Meanwhile, the NTr 23d is turned off by the signal cctrl 5 having H level input to the NOT circuit 23s. Then, the signal cctrl 6 is controlled so as to be at L level, whereby the bias voltage signal BIAS 1 is output as the outBIAS 3 to the current detecting circuit 60.

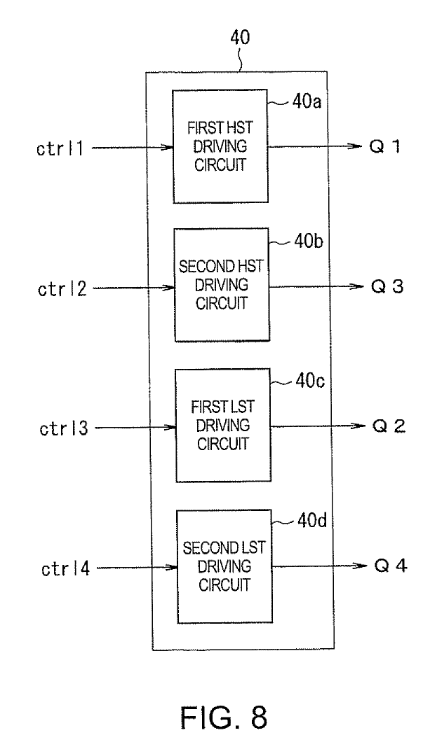

Next, a structure of the transistor driving circuit 40 will be described with reference to FIG. 8.

FIG. 8 is a block diagram showing the structure of the transistor driving circuit 40.

As shown in FIG. 8, the transistor driving circuit 40 includes a first high-side transistor (HST) driving circuit 40a and a second HST driving circuit 40b. The first HST driving circuit 40a controls on and off of the N-channel DMOSFET Q1 of the H-bridge circuit 50 based on a control signal ctrl 1 from the control circuit 10. The second HST driving circuit 40b controls on and off of the Q3 of the H-bridge circuit 50 based on a control signal ctrl 2 from the control circuit 10.

The transistor driving circuit 40 further includes a first low-side transistor (LST) driving circuit 40c and a second LST driving circuit 40d. The first low-side transistor (LST) driving circuit 40c controls on and off of the Q2 of the H-bridge circuit 50 based on a control signal ctrl 3 from the control circuit 10. The second LST driving circuit 40d controls on and off of the Q4 of the H-bridge circuit 50 based on a control signal ctrl 4 from the control circuit 10.

The control signals ctrl 1 to ctrl 4 from the control circuit 10 are signals (such as pulse width modulation (PWM) signals) that control on and off of the DMOSFETs Q1 to Q4 according to the driving mode of the motor 2. L-level control signals corresponding to the respective DMOSFETs turn on the Q1 to the Q4, whereas H-level control signals corresponding thereto turn off the Q1 to the Q4, in the transistor driving circuit 40.

The transistor driving circuit 40 is driven by driving power supplied from the DC/DC converter 31 and the LDO 32. Accordingly, driving the converter 31 and the LDO 32 with low power consumption allows the transistor driving circuit 40 to be also driven with low power.

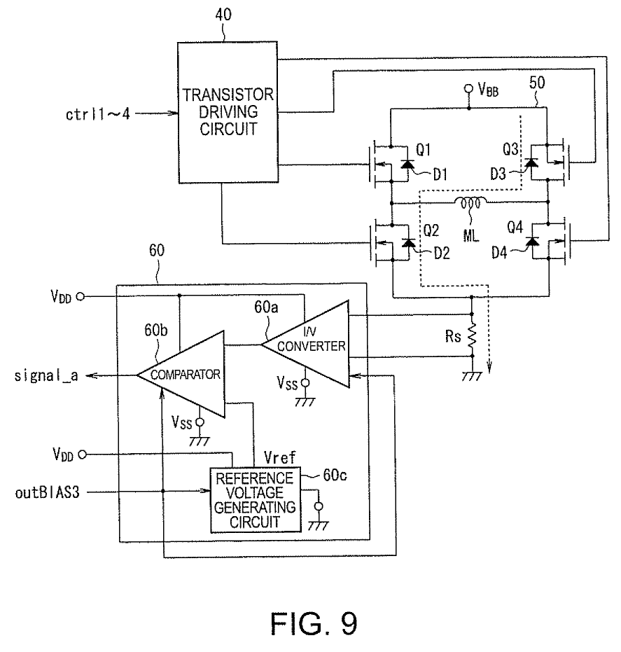

Next will be described detailed structures of the H-bridge circuit 50 and the current detecting circuit 60, with reference to FIG. 9,

FIG. 9 is a diagram showing the detailed structures of the H-bridge circuit 50 and the current detecting circuit 60.

As described above, the H-bridge circuit 50 includes the four N-channel DMOSFETs Q1 to Q4 serving as switching elements. Among the elements, the Q1 and the Q3 are arranged at a high side of the bridge circuit and the Q2 and the Q4 are arranged at a low side thereof to connect the Q1 to the Q4 so as to form an H-bridge configuration.

Specifically, a source terminal of the Q1 is electrically connected to a drain terminal of the Q2 to form an output terminal OUTA, and a source terminal of the Q3 is electrically connected to a drain terminal of the Q4 to form an output terminal OUTB. The output terminal OUTA outputs a signal from a connecting point between the Q1 and the Q2, and an output terminal OUTB outputs a signal from a connecting point between the Q3 and the Q4. The output terminals OUTA and OUTB are connected to the DC motor 2. Reference numerals D1 to D4 denote body diodes parasitically included in the Q1 to the Q4.

The driving voltage VBB is supplied from a driving voltage source of the motor 2 to the high side of the H-bridge circuit 50, namely, to drain terminals of the Q1 and the Q3. Meanwhile, the low side of the H-bridge circuit 50, namely, source terminals of the Q1 and the Q4 are connected to a ground via a current detecting resistance Rs.

A gate terminal of each of the Q1 to the Q4 of the H-bridge circuit 50 is electrically connected to a drive line extended from the transistor driving circuit 40 to control driving of the Q1 to the Q4 independently, based on driving potential and driving current supplied via the drive line.

As shown in FIG. 9, the current detecting circuit 60 includes an I/V converting circuit 60a, a comparator 60b, and a reference voltage generating circuit 60c.

Input terminals of the I/V converting circuit 60a are electrically connected to opposite ends of the current detecting resistance Rs of the H-bridge circuit 50 and an output terminal of the I/V converting circuit 60a is electrically connected to an input terminal of the comparator 60b. The I/V converting circuit 60a receives electric current flowing through the resistance Rs of the H-bridge circuit 50 and converts the current to a voltage to input to the comparator 60b.

An output terminal of the comparator 60b is electrically connected to the input terminal of the control circuit 10. The comparator 60b compares a voltage Vs input from the I/V converting circuit 60a with a reference voltage Vref input from the reference voltage generating circuit 60c. Then, the comparator 60b outputs an H-level comparison signal #a when the voltage Vs has a level equal to or larger than that of the reference voltage Vref, and outputs an L-level comparison signal #a when the level of the Vs is smaller than that of the Vref.

An electric current is flowing through the Rs is, for example, an electric current that passes through a coil ML of the motor 2 (as indicated by a dotted-line arrow in FIG. 9) when the Q3 of the H-bridge circuit 50 is in an on state and when the Q2 is turned on from off and thereby electric current begins to flow between the drain and the source of the Q2, as shown in FIG. 9.

Next will be described actual operation of the motor driving device 1 according to the embodiment.

In the internal register of the control circuit 10, the normal mode is set when the xsleep bit is “1” and the IDLE 1 bit and the IDLE 2 bit are both “0”. When the xsleep bit is set to “0”, the sleep mode is set as the supply mode, regardless of the statuses of the other bits. When the xsleep bit is “1”; the IDLE 1 bit is “1”; and the IDLE 2 bit is “0”, the idle mode 1 is set. When the xsleep bit is “1”; the IDLE 1 bit is “0”; and the IDLE 2 bit is “1”, the idle mode 2 is set.

Additionally, in the case of the normal mode, the cctrl 1 bit, the cctrl 3 bit, and the cctrl 5 bit are set to “1” and the cctrl 2 bit, the cctrl 4 bit, and the cctrl 6 bit are set to “0”.

In the sleep mode, the cctrl 2 bit and the cctrl 4 bit are set to “1” and the cctrl 1 bit, the cctrl 3 bit, the cctrl 5 bit, and the cctrl 6 bit are set to “0”.

Furthermore, when the idle modes 1 and 2 are set, the cctrl 2 bit and the cctrl 3 bit are set to “1” and the cctrl 1 bit, the cctrl 4 bit, the cctrl 5 bit, and the cctrl 6 bit are set to “0”.

When main power of the motor driving device 1 is turned on and thereby the motor 2 starts to be driven, the control circuit 10 sets the normal mode in the internal register. In other words, when a setting value of the supply mode is assumed to be structured such that the xsleep bit, the IDLE 1 bit, the IDLE 2 bit, and the cctrl 1 to the cctrl 6 bits are arranged in the sequence order from a most significant bit to a least significant bit, a setting value “100101010” is set in the register in the normal mode.

The control circuit 10 reads the setting value of the normal mode set in the internal register to output a setting signal set with the content of the setting value to the driving signal supply control circuit 20.

Based on “100101010” as the content of the setting signal set, the driving signal supply control circuit 20 starts supply control of the driving signals of the power supply circuit 30 and the current detecting circuit 60.

In the normal mode, the signal xsleep of H level and the signals IDLE 1 and the IDLE 2 of L level are input to the first driving signal supply control circuit 21.

Thereby, the L-level signal IDLE 1 is input to a select signal input terminal S of the selector 21c. Then, the selector 21c outputs a first clock signal (the normal CLK) to the first input terminal of the first AND circuit 21e. The L-level signal IDLE 2 is reversed to the H level by the NOT circuit 21d, and then, input to the second input terminal of the first AND circuit 21e. The first AND circuit 21e outputs the first clock signal input to the first input terminal thereof, as it is, to the first input terminal of the second AND circuit 21f. The H-level signal xsleep is input to the second input terminal of the second AND circuit 21f, whereby the second AND circuit 21f outputs the first clock signal input to the first input terminal thereof as it is to the voltage boosting clock generating circuit 21g. The voltage boosting clock generating circuit 21g generates the voltage boosting clock signals CLKP and CLKN from the input first clock signal to supply the generated voltage boosting clock signals to the PTr 33 and the NTr 34 of the DC/DC converter 31.

The first bias voltage outputting circuit 22a of the second driving signal supply control circuit 22 receives an H-level signal cctrl 1 and an L-level signal cctrl 2, and the second bias voltage outputting circuit 22b thereof receives an H-level signal cctrl 3 and an L-level signal cctrl 4. The third bias voltage outputting circuit 22c receives an H-level signal cctrl 5 and an L-level signal cctrl 6.

Accordingly, in the first bias voltage outputting circuit 22a, the H-level signal cctrl 1 is input to a gate terminal of the NTr 23m to turn on the NTr 23m so as to allow the signal IBIAS 1 to flow. The bias voltage signal BIAS 1 in accordance with an electric current amount of the signal IBIAS 1 is supplied from the output terminal of the NTr 23m to the input terminal of the first transmission gate 23p of the first bias voltage selecting circuit 34.

Meanwhile, the L-level signal cctrl 2 is input to the gate terminal of the NTr 23n to turn off the NTr 23n, thereby stopping the signal IBIAS 2 from flowing.

Furthermore, in the first bias voltage selecting circuit 34, the H-level signal cctrl 1 is supplied to the control signal input terminal of the first transmission gate 23p, and the L-level signal cctrl 2 is supplied to the control signal input terminal of the second transmission gate 23r. Thereby, the bias voltage signal BIAS 1 as an output from the first transmission gate 23p is output as the outBIAS 1 from the output terminal 3 to be supplied to the DC/DC converter 31.

As a result, the DC/DC converter 31 receives the first clock signal and the bias voltage signal outBIAS 1 generated from the IBIAS 1.

Additionally, the second bias voltage outputting circuit 22b and the second bias voltage selecting circuit 35 operate in the same manner as the first bias voltage outputting circuit 22a and the first bias voltage selecting circuit 34 to supply the bias voltage signal outBIAS 2 generated from the IBIAS 1 to the LDO 32.

The third bias voltage outputting circuit 22c operates in the same manner as the first bias voltage outputting circuit 22a. The third bias voltage outputting circuit 22 supplies the bias voltage signal BIAS 1 generated by voltage conversion of the bias current signal IBIAS 1 to the input terminal of the first transmission gate 23p of the third bias voltage selecting circuit 36.

In the third bias voltage selecting circuit 36, the control signal input terminal of the first transmission gate 23p receives the H-level signal cctrl 5, and the control signal input terminal of the second transmission gate 23r receives the L-level signal cctrl 6. Additionally, the input terminal of the NOT circuit 23s receives the H-level signal cctrl 5.

Thereby, the first transmission gate 23p is turned on; the second transmission gate is turned off; and the NTr 23d is also turned off. Accordingly, the bias voltage signal BIAS 1 output from the first transmission gate 23p is output as the outBIAS 3 from the output terminal 3 to be supplied to the current detecting circuit 60.

Thus, the DC/DC converter 31 is driven in the normal mode to supply power having the voltage VBB+VGH to the first and the second HST driving circuits 40a and 40b. Additionally, the LDO 32 is driven in the normal mode to supply power having a voltage VGL to the first and the second LST driving circuits 40c and 40d.

Then, the first and the second HST driving circuits 40a, 40b and the first and the second LST driving circuits 40c, 40d are also driven in the normal mode to drive the Q1 to Q4 based on control contents designated by the control signals cctrl 1 to 4 from the control circuit 10, thereby driving the motor 2.

Furthermore, the bias voltage signal generated from the IBIAS 1 is also supplied as the outBIAS 3 to the current detecting circuit 60, thereby allowing the current detecting circuit 60 to be driven in the normal mode.

Next, when the status of the motor 2 is shifted from the driving status to the standby status, the control circuit 10 sets one of the sleep mode, the idle mode 1, and the idle mode 2 in the internal register. In order to set the supply mode, a setting algorithm is pre-programmed by analyzing a driving program for the load, for example. In this case, instead of automatic setting by the control circuit 10, for example, a user may set the supply mode by manually operating an input device.

Among the supply modes, first, a sleep mode operation will be described.

In the sleep mode, the control circuit 10 sets a setting value “0**010100” in the register. A “*” bit may be either 0 or 1.

The control circuit 10 reads the setting value of the sleep mode set in the internal register to output a setting signal set indicating the content of the setting value to the driving signal supply control circuit 20.

The driving signal supply control circuit 20 starts supply control of a driving signal of each of the power supply circuit 30 and the current detecting circuit 60 based on the content “0**010100” of the setting signal set.

In the sleep mode, the signal xsleep having L level is input to the first driving signal supply control circuit 21.

Then, the second input terminal of the second AND circuit 21f receives the L-level signal xsleep to thus output an L-level signal to the voltage boosting clock generating circuit 21g. Thereby, the voltage boosting clock generating circuit 21g supplies an H-level signal (a constant potential signal) to the PTr 33 of the DC/DC converter 31 and supplies an L-level signal (a constant potential signal) to the NTr 34.

In the second driving signal supply control circuit 22, the first bias voltage outputting circuit 22a receives the signal cctrl 1 of L level and the signal cctrl 2 of H level; the second bias voltage outputting circuit 22b receives the signal cctrl 3 of L level and the signal cctrl 4 of H level; and the third bias voltage outputting circuit 22c receives the signals cctrl 5 and cctrl 6 having L level.

Accordingly, in the first bias voltage outputting circuit 22a, the L-level signal cctrl 1 is input to the gate terminal of the NTr 23m to turn off the NTr 23m, thereby stopping the IBIAS 1 from flowing through.

Meanwhile, the H-level signal cctrl 2 is input to the gate terminal of the NTr 23n to turn on the NTr 23n so as to allow the IBIAS 2 to flow through, whereby the bias voltage signal BIAS 2 corresponding to an electric current amount of the IBIAS 2 is supplied from the output terminal 2 to the input terminal of the second transmission gate 23r of the first bias voltage selecting circuit 34.

Additionally, in the first bias voltage selecting circuit 34, the control signal input terminal of the first transmission gate 23p receives the L-level signal cctrl 1, and the control signal input terminal of the second transmission gate 23r receives the H-level signal cctrl 2. Thus, the bias voltage signal BIAS 2 as an output from the second transmission gate 23r is output as the outBIAS 1 from the output terminal 3 to be supplied to the DC/DC converter 31.

As a result, no clock signal is supplied to the DC/DC converter 31, although the bias voltage signal outBIAS 1 generated from the signal IBIAS 2 having a smaller amount of electric current than that of the signal IBIAS 1 is supplied to the converter.

Furthermore, the second bias voltage outputting circuit 22b and the second bias voltage selecting circuit 35 operate in the same manner as the first bias voltage outputting circuit 22a and the first bias voltage selecting circuit 34 to supply the bias voltage signal out BIAS 2 generated from the bias current signal IBIAS 2 to the LDO 32.

The LDO 32 receives the bias voltage signal outBIAS 2 generated from the signal IBIAS 2 having a smaller electric current amount than that of the bias current signal IBIAS 1.

In the third bias voltage outputting circuit 22c, the L-level signal cctrl 5 is input to the gate terminal of the NTr 23m, and the L-level signal cctrl 6 is input to the gate terminal of the NTr 23n. Thereby, the NTr 23m and the NTr 23n are both turned off, thereby stoppling the signals IBIAS 1 and IBIAS 2 from flowing through. In the third bias voltage selecting circuit 36, the L-level signal cctrl 5 is input to the control signal input terminal of the first transmission gate 23p; the L-level signal cctrl 6 is input to the control signal input terminal of the second transmission gate 23r; and the L-level signal cctrl 5 is input to the input terminal of the NOT circuit 23s.

Consequently, the first transmission gate 23p is turned off; the second transmission gate is also turned off; and the NTr 23d is turned on. Thus, a bias voltage signal having a ground potential is output as the outBIAS 3 from the output terminal 3 to be supplied to the current detecting circuit 60.

Accordingly, both of the bias current signals IBIAS 1 and IBIAS 2 are not flown through, so that the outBIAS 3 is substantially not supplied to the current detecting circuit 60.

As a result, since the DC/DC converter 31 stops voltage boosting operation, power having the voltage VBB+VGH is not supplied to the first and the second HST driving circuits 40a and 40b. Additionally, The DC/DC converter 31 and the LDO 32 can be driven with low power consumption by the bias voltages outBIAS 1 and outBIAS 2 generated from the bias current signal IBIAS 2.

The bias voltage signal outBIAS 3 is not supplied to the current detecting circuit 60, thus stopping the current detecting circuit 60 from operating.

Next, operation in the idle mode 1 will be described.

When the idle mode 1 is set, the control circuit 10 sets a setting value “110100100” in the register.

The control circuit 10 reads the setting value of the idle mode 1 set in the internal register to output a setting signal set indicating a content of the setting value to the driving signal supply control circuit 20.

Based on the content “110100100” of the setting signal set, the driving signal supply control circuit 20 starts supply control of driving signals of the power supply circuit 30 and the current detecting circuit 60.

In the idle mode 1, the first driving signal supply control circuit 21 receives the signal xsleep of H level, the signal IDLE 1 of H level, and the IDLE 1 of L level.

Then, the H-level signal IDLE 1 is input to the select signal input terminal S of the selector 21c. The selector 21c outputs a second clock signal (a low-speed CLK) to the first input terminal of the first AND circuit 21e. The NOT circuit 21d reverses the L-level signal IDLE 2 to the H level signal. The H-level signal IDLE 2 is input to the second input terminal of the first AND circuit 21e, and thus, the first AND circuit 21e outputs the second clock signal input to the first input terminal, as it is, to the first input terminal of the second AND circuit 21f. The second input terminal of the second AND circuit 21f receives the H-level signal xsleep. Thus, the second AND circuit 21f outputs the second clock signal input to the first input terminal, as it is, to the voltage boosting clock generating circuit 21g. Thereby, the voltage boosting clock generating circuit 21g generates the voltage boosting clock signals CLKP and CLKN from the input second clock signal to supply the generated signals to the PTr 33 and the NTr 34 of the DC/DC converter 31.

In the second driving signal supply control circuit 22, the first bias voltage outputting circuit 22a receives the signal ctrl 1 of H level and the signal cctrl 2 of L level; the second bias voltage outputting circuit 22b receives the signal cctrl 3 of L level and the signal cctrl 4 of H level; and the third bias voltage outputting circuit 22c receives the signals cctrl 5 and cctrl 6 of L level.

Accordingly, the first bias voltage outputting circuit 22a operates in the same manner as the normal mode operation described above, whereas the second and the third bias voltage outputting circuits 22b and 22c operate in the same manner as the sleep mode operation above.

Consequently, the DC/DC converter 31 receives a voltage boosting clock signal having a lower frequency than in the normal driving status and also receives the same bias voltage signal outBIAS 1 as in the normal driving status. Therefore, allowing the voltage boosting clock signal to be back to a normal-clock signal from the low-frequency signal can lead to returning to the normal driving status.

Additionally, the bias voltage signal outBIAS 2 is supplied to the LDO 32 with low power consumption, whereas the bias voltage signal outBIAS 3 is not supplied to the current detecting circuit 60.

Thus, the DC/DC converter 31 performs voltage boosting operation at a lower switching speed than in the normal driving status. Additionally, an amount of the bias current supplied to the LDO 32 is smaller than in the normal driving status, whereas the current detecting circuit 60 stops operation.

Next will be described operation in the idle mode 2.

In the idle mode 2, the control circuit 10 sets a setting value “101100100” in the register.

The control circuit 10 reads the setting value of the idle mode 2 set in the internal register to output a setting signal set indicating a content of the value to the driving-signal supply control circuit 20.

Based on “101100100” as the content of the setting signal set, the driving signal supply control circuit 20 starts supply control of the driving signals of the power supply circuit 30 and the current detecting circuit 60.

In the idle mode 2, the signal xsleep of H level, the signal IDLE 1 of L level, and the signal IDLE 2 of H level are input to the first driving signal supply control circuit 21.

The L-level signal IDLE 1 is input to the select signal input terminal S of the selector 21c, whereby the selector 21c outputs a first clock signal to the first input terminal of the first AND circuit 21e. The signal IDLE 2 is reversed from H level to L level by the NOT circuit 21d to be input to the second input terminal of the first AND circuit 21e. Thus, the first AND circuit 21e outputs an L-level signal to the first input terminal of the second AND circuit 21f. The H-level signal xsleep is input to the second input terminal of the second AND circuit 21f. Accordingly, the second AND circuit 21f outputs the L-level signal input to the first input terminal, as it is, to the voltage boosting clock generating circuit 21g. As a result, as in the above-described sleep mode, no voltage boosting clock signal is supplied to the PTr 33 and the NTr 34 of the DC/DC converter 31.

The operation of the second driving signal supply control circuit 22 is the same as in the idle mode 1 described above.

Consequently, the DC/DC converter 31 stops the voltage boosting operation, so that the power having the voltage VBB+VGH is not supplied to the first and the second HST driving circuits 40a and 40b. However, the bias voltage signal outBIAS 1 is supplied as in the normal driving status. Accordingly, supplying a normal-frequency voltage boosting clock signal can lead to returning to the normal driving state.

The bias voltage signal outBIAS 2 is supplied to the LDO 32 with low power consumption, whereas the bias voltage signal outBIAS 3 is not supplied to the current detecting circuit 60, which thus stops operation.

As described hereinabove, in the embodiment, based on each setting value of the supply mode set in the internal register of the control circuit 10, the driving signal supply control circuit 20 can control the contents of the driving signals that drive the power supply circuit 30 supplying driving power to the transistor driving circuit 40 driving the high-side transistors Q1, Q3 and the low-side transistors Q2, Q4 of the H-bridge circuit 50 driving the motor 2 and the current detecting circuit 60. Particularly, in the standby status of the motor 2, the three supply modes: the sleep mode and the idle modes 1, 2 can be set. Accordingly, the driving signal supply control circuit 20 can control independently each of the driving signals supplied to the DC/DC converter 31 and the LDO 32 of the power supply circuit 30, based on the supply contents corresponding to the three modes.

Furthermore, the driving signal supply control circuit 20 can control (reduce) independently the supply of the bias current signal for generating the bias voltage signal to the circuit that supplies the bias voltage to the DC/DC converter 31. Additionally, the driving signal supply control circuit 20 can also independently perform the supply control (frequency reduction or supply stoppage) of the voltage boosting clock signals to the switching elements of the DC/DC converter 31.

Still furthermore, the driving signal supply control circuit 20 can independently control (reduce) the supply of the bias current signal for generating the bias voltage signal to the circuit that supplies the bias voltage to the LDO 32, as well as can independently perform the supply control (frequency reduction or supply stoppage) of the bias current signal for generating the bias voltage signal to the circuit supplying the bias voltage to the current detecting circuit 60.

Thus, the driving signal supply control circuit 20 can independently control the supply of the driving signals to the DC/DC converter 31, the LDO 32, and the current detecting circuit 60, thereby controlling with appropriate low-power consumption according to the driving status of the load.

In the embodiment above, the setting of the supply content (the supply mode) in the internal register of the control circuit 10 corresponds to setting by the supply content setting unit described in the first aspect of the invention. The supply control of driving signals by the control circuit 10 and the driving signal supply control circuit 20 corresponds to the supply control by the driving signal supply control unit described in the first aspect. The first bias voltage selecting circuit 34 and the DC/DC converter 31 correspond to the first power supply circuit described in the first aspect. The second bias voltage selecting circuit 35 and the LDO 32 correspond to the second power supply circuit described in the first aspect. The first and the second HST driving circuits 40a and 40b correspond to the first driving circuit described in the first aspect. The first and the second LST driving circuits 40c and 40d correspond to the second driving circuit described in the first aspect. The NTr 23m and the NTr 23n, respectively, in the first and the second bias voltage outputting circuits 22a and 22b correspond to the third transistor and the fourth transistor, respectively, described in the fifth preferred feature of the first aspect.

In the above embodiment, the driving signal supply control circuit 20 performs not only the control of the supply content of the bias voltage signal and the signal cctrl 1 supplied to the first to the third bias voltage selecting circuits 34 to 36, but also the control of the supply content of the switching signals supplied to the switching elements of the DC/DC converter 31. However, the driving signal supply control circuit 20 may perform only the former control. In this case, the first driving signal supply control circuit 21 is not required, and thus, the driving signal supply control unit includes only the second driving signal supply control circuit 22.

In the above case, the setting of the supply content (the supply mode) in the internal register of the control circuit 10 corresponds to setting by a supply content setting unit described in the second aspect of the invention. The supply control of the driving signals by the control circuit 10 and the second driving signal supply control circuit 22 corresponds to the supply control by the driving signal supply control unit described in the second aspect. The DC/DC converter 31 and the LDO 32, respectively, correspond to the first power supply circuit and the second power supply circuit, respectively, described in the second aspect. The first and the second HST driving circuits 40a and 40b correspond to the first driving circuit described in the second aspect, and the first and the second LST driving circuits 40c and 40d correspond to the second driving circuit described in the second aspect. The NTr 23m and the NTr 23n, respectively, in the first to the third bias voltage outputting circuits 22a to 22c correspond to the third transistor and the fourth transistor, respectively, described in the first preferred feature of the second aspect. The first bias voltage outputting circuit 22a and the first bias voltage selecting circuit 34 correspond to the first bias voltage supply circuit described in the first preferred feature of the second aspect. The second bias voltage outputting circuit 22b and the second bias voltage selecting circuit 35 correspond to the second bias voltage supply circuit described in the first preferred feature of the second aspect. The third bias voltage outputting circuit 22c and the third bias voltage selecting circuit 36 correspond to the third bias current supply circuit described in the second preferred feature of the second aspect.

In the above embodiment, the driving signal supply control circuit 20 controls the bias current signals IBIAS 1 and IBIAS 2 for generating the bias voltage signals BIAS 1 and BIAS 2 to control the supply of the driving signals (outBIAS) supplied to the DC/DC converter 31, the LDO 32, and the current detecting circuit 60. However, any other embodiments may be utilized as long as the embodiments enables the amount of bias current supplied to the controlled objects such as the DC/DC converter 31, the LDO 32, and the current detecting circuit 60 to be controlled.

Additionally, in the above embodiment, the driving signal supply control circuit 20 controls the supply of the driving signals supplied to the DC/DC converter 31, the LDO 32, and the current detecting circuit 60. Alternatively, when there is provided another circuit supplying a driving signal such as a bias voltage signal, the circuit may also be controlled.

Additionally, in the above embodiment, the transistors Q1 to Q4 are all the N-channel DMOSFETs. Instead of that, the high-side transistors Q1 and Q3 may be P-channel transistors, or may not be the DMOSFETs but any other output transistors, insulated gate bipolar transistors (IGBTs), or the like.

Furthermore, the above embodiment uses the H-bridge circuit driving the DC motor, but may alternatively use, for example, any other bridge circuit driving loads such as an electromagnetic valve. In particular, the electromagnetic valve allows electric current to flow in only one direction from an opening side portion to a closing side portion of the valve, so that a half-bridge circuit can be provided.

What is claimed is:

1. A load driving device that is coupled a bridge circuit, the bridge circuit including a first transistor to which a first voltage is applied and a second transistor to which a second voltage is applied that is lower than the first voltage, the bridge circuit being electrically connected to a load whose conduction is controlled by the first transistor and the second transistor, the load driving device comprising:
(ii) a first driving circuit that drives the first transistor;
(iii) a second driving circuit that drives the second transistor;
(iv) a first power supply circuit that supplies a first driving power to the first driving circuit;
(v) a second power supply circuit that supplies a second driving power to the second driving circuit;
(vi) a driving signal supply control unit that provides a first driving signal to the first power supply circuit and a second driving signal to the second power supply circuit; and
(vii) a supply content setting unit that sets a supply content according to a status of the load,
the driving signal supply control unit generating the first driving signal and the second driving signal according to the supply content,
the driving signal supply control unit controlling independently the first driving signal and the second driving signal.

2. The load driving device according to claim 1,
the first power supply circuit including a DC/DC converter,
the DC/DC converter including a switching element,
the second power supply circuit including a linear regulator,
the supply content set by the supply content setting unit being one of a first supply content and a second supply content, and
when the supply content setting unit sets the first supply content, the driving signal supply control unit does not supply a switching signal to the switching element, and the driving signal supply control unit controls so that a bias voltage is less than a bias voltage in the normal driving status, the bias voltage is provided to the first power supply circuit, and
when the supply content setting unit sets the second supply content, the driving signal supply control unit supplies the switching signal to the switching element, and the driving signal supply control unit controls so that the bias voltage is less than a bias voltage in the normal driving status, the bias voltage is provided to the second power supply circuit.

3. The load driving device according to claim 2,
the driving signal supply control unit including:
a first switching signal generating section that generates a first switching signal in the normal driving status and outputs the first switching signal;
a second switching signal generating section that generates a second a witching signal, a frequency of the second switching signal is lower than a frequency of the first switching signal, the second switching signal generating section outputs the second switching signal; and
a switching signal supply control section that supplies the first switching signal to the switching element in the normal driving status,
the switching signal supply control section not supplying the first switching signal and the second switching signal to the switching element when the supply content setting unit sets the first supply content, and
the switching signal supply control section supplying the second switching signal to the switching element when the supply content setting unit sets the second supply content.

4. The load driving device according to claim 1,
the first power supply circuit including a DC/DC converter including at least one switching element,
the second power supply circuit including a linear regulator,
the supply content set by the supply content setting unit being one of a first supply content and a second supply content, and
when the supply content setting unit sets the first supply content, the driving signal supply control unit stops supply of a switching signal as one of the driving signals supplied to the switching element and controls a supply content of a bias voltage signal as one of the driving signals to the first and the second power supply circuits such that an amount of bias current supplied is reduced to less than in the normal driving status,
when the supply content setting unit sets the second supply content, the driving signal supply control unit stops supply of the switching signal to the switching element and controls the supply content of the bias voltage signal to the second power supply circuit such that the amount of the bias current supplied is reduced to less than in the normal driving status.

5. The load driving device according to claim 2,
the driving signal supply control unit including:
a first bias voltage outputting circuit that includes a first voltage converting section and a second voltage converting section, the first voltage converting section converting a first bias current signal to a first bias voltage signal and outputting the first bias voltage signal, and the second voltage converting section converting a second bias current signal to a second bias voltage signal and outputting the second bias voltage signal;
a first bias voltage outputting circuit that includes a third voltage converting section and a forth voltage converting section, the third voltage converting section converting a third bias current signal to a third bias voltage signal and outputting the third bias voltage signal, and the forth voltage converting section converting a forth bias current signal to a forth bias voltage signal and outputting the forth bias voltage signal;
a first bias voltage selecting circuit that receives the first bias voltage signal and the second bias voltage signal from the first bias voltage outputting circuit, select one of the first bias voltage outputting circuit, and outputs one of the first bias voltage signal and the second bias voltage signal;
a second bias voltage selecting circuit that receives the third bias voltage signal and the forth bias voltage signal from the second bias voltage outputting circuit, select one of the third bias voltage signal and the forth bias voltage signal, and outputs one of the third bias voltage signal and the forth bias voltage signal; and
a bias current supply control section,
in the normal driving status, the bias current supply control section supplying the first bias current signal to the first bias voltage outputting circuit and supplying the third bias current signal to the second bias voltage outputting circuit,
when the supply content setting unit sets the first supply content, the bias current supply control section supplying the second bias current signal to the first bias voltage outputting circuit and supplying the forth bias current signal to the second bias voltage outputting circuit, and
when the supply content setting unit sets the second supply content, the bias current supply control section supplying the first bias current signed to the first bias voltage outputting circuit and supplying the forth bias current signal to the second bias voltage outputting circuit.

6. The load driving device according to claim 2,
the driving signal supply control unit including:
a first bias voltage outputting circuit having a third transistor controlled by a first input voltage, a forth transistor controlled by a second input voltage, a first bias converting circuit that receives a first bias current signal via the third transistor and converts the first bias current signal to a first bias voltage signal, a second bias converting circuit that receives a second bias current signal via the forth transistor and converts the second bias current signal to a second bias voltage signal;
a second bias voltage outputting circuit having a fifth transistor controlled by a third input voltage, a sixth transistor controlled by a forth input voltage, a third bias converting circuit that receives a third bias current signal via the fifth transistor and converts the third bias current signal to a third bias voltage signal, a forth bias converting circuit that receives a forth bias current signal via the sixth transistor and converts the forth bias current signal to a forth bias voltage signal;
a first bias voltage selecting circuit selecting one of the first bias voltage signal and the second bias voltage signal based on the first input voltage and the second input voltage, the first bias voltage selecting circuit outputting one of the first bias voltage signal and the second bias voltage signal to the first power supply circuit;
a second bias voltage selecting circuit selecting one of the third bias voltage signal and the forth bias voltage signal based on the first input voltage and the second input voltage, the second bias voltage selecting circuit outputting one of the third bias voltage signal and the forth bias voltage signal to the second power supply circuit; and
a bias current supply control section supplying the first input voltage to the third transistor, the second input voltage to the forth transistor, the third input voltage to the fifth transistor and the forth input voltage to the sixth transistor,
in the normal driving status, the third transistor and the fifth transistor is set on state and the forth transistor and the sixth transistor is set off state,
when the supply content setting unit sets the first content, the third transistor and the fifth transistor is set off state and the forth transistor and the sixth transistor is set on state, and
when the supply content setting unit sets the second content, the third transistor and the sixth transistor is set on state and the forth transistor and the fifth transistor is set off state.

7. The load driving device according to claim 1,
the bad driving device further including a current detecting circuit detecting an amount of current flowing through the load, and
based on the supply content set by the supply content setting unit, the driving signal supply control unit controlling a supply content of a driving signal supplied to the current detecting circuit such that the current detecting circuit stops operating or is driven with lower power consumption than in the normal driving status.

8. The load driving device according to claim 2,
the load driving device further including a current detecting circuit detecting an amount of current flowing through the load, and
when the supply content setting unit sets either the first or the second supply content, the driving signal supply control unit supplying a bias voltage signal as one of the driving signals to the current detecting circuit at a potential where no bias current signal flows.

9. A driving signal supply control semiconductor device, comprising:
(i) an H-bridge circuit including a first transistor and a second transistor, the first transistor and the second transistor being electrically connected to a load as an object to be driven and being turned on or off to energize or de-energize the load;
(ii) a first driving circuit driving the first transistor;
(iii) a second driving circuit driving the second transistor;
(iv) a first power supply circuit supplying driving power to the first driving circuit;
(v) a second power supply circuit supplying driving power to the second driving circuit;
(vi) at least a first bias voltage supply circuit and a second bias voltage supply circuit, the first bias voltage supply circuit supplying a bias voltage to the first power supply circuit and the second bias voltage supply circuit supplying a bias voltage to the second power supply circuit;
(vii) a supply content setting unit setting a supply content of each of driving signals regarding low power driving of the load driving device according to a standby status of the load; and
(viii) a driving signal supply control unit controlling supply of the driving signals to the first and the second power supply circuits, the driving signal supply control unit controlling independently contents of the driving signals supplied to each of the first and the second bias voltage supply circuits such that the load driving device is driven with lower power consumption than in a normal driving status of the load driving device, based on the supply content set by the supply content setting unit.

10. The load driving device according to claim 9,
the first bias voltage supply circuit including:
a first voltage converting section converting a first bias current signal to a first bias voltage signal to output the first bias voltage signal;
a second voltage converting section converting a second bias current signal to a second bias voltage signal to output the second bias voltage signal,
a third transistor turned on or off by a first input voltage, the third transistor supplying the first bias current signal to the first voltage converting section in an on state and stopping the supply of the first bias current signal in an off state;
a fourth transistor turned on or off by a second input voltage, the fourth transistor supplying the second bias current signal having a smaller current level than the first bias current signal to the second voltage converting section in an on state and stopping the supply of the second bias current signal in an off state; and
a first bias voltage selecting section selecting the bias voltage signal supplied to the first power supply circuit in the first and the second bias voltage signals output from the first bias voltage outputting circuit based on the first and the second input voltages, and
the second bias voltage supply circuit including:
a first voltage converting section converting a first bias current signal to a first bias voltage signal to output the first bias voltage signal;
a second voltage converting section converting a second bias current signal to a second bias voltage signal to output the second bias voltage signal,
a third transistor turned on and off by a first input voltage, the third transistor supplying the first bias current signal to the first voltage converting section in an on state and stopping the supply of the first bias current signal in an off state,
a fourth transistor turned on and off by a second input voltage, the fourth transistor supplying a second bias current signal having a smaller current level than the first bias current signal to the second voltage converting section in an on state and stopping the supply of the second bias current signal in an off state, and
a second bias voltage selecting section selecting the bias voltage signal supplied to the second power supply circuit in the first and the second bias voltage signals output from the second bias voltage outputting circuit based on the first and the second input voltages;
the supply content set by the supply content setting unit includes a first supply content and a second supply content; and,
in the normal driving status, the driving signal supply control unit supplies the first and the second input voltages to driving terminals of the third and the fourth transistors of the first and the second bias voltage supply circuits to turn on the third transistor and turn off the fourth transistor in the normal driving status, the driving signal supply control unit supplying the first and the second input voltages to the driving terminals of the third and the fourth transistors of the first and the second bias voltage supply circuits to turn off the third transistor and turn on the fourth transistor when the supply content setting unit sets the first supply content, whereas supplying the first and the second input voltages to the driving terminals of the third and the fourth transistors of the first bias voltage supply circuit to turn on the third transistor and turn off the fourth transistor and supplying the first and the second input voltages to the driving terminals of the third and the fourth transistors of the second bias voltage supply circuit to turn off the third transistor and turn on the fourth transistor when the supply content setting unit sets the second supply content.

11. The load driving device according to claim 10, wherein the load driving device further includes a current detecting circuit detecting an amount of current flowing through the load and a third bias voltage supply circuit supplying a bias voltage to the current detecting circuit; and the driving signal supply control unit controls to stop supply of the driving signals to the third bias voltage supply circuit when the supply content setting unit sets the first supply content or the second supply content.
